(19) United States
(12) Patent Application Publication
(10) Pub. No.: US 2025/0351638 A1
(43) Pub. Date: Nov. 13, 2025

(54) DISPLAY DEVICE AND METHOD OF MANUFACTURING THE SAME

(71) Applicant: Samsung Display Co., LTD., Yongin-si (KR)

(72) Inventors: Jae Hoon JUNG, Yongin-si (KR); So Young YEO, Yongin-si (KR)

(73) Assignee: Samsung Display Co., LTD., Yongin-si (KR)

(21) Appl. No.: 19/074,757

(22) Filed: Mar. 10, 2025

(30) Foreign Application Priority Data
May 9, 2024 (KR) 10-2024-0061324

(51) Int. Cl. H10H 29/14; H10H 29/01; H10H 29/39; H10H 29/80

(52) U.S. Cl. CPC H10H 29/142; H10H 29/012; H10H 29/39; H10H 29/8325

(57) ABSTRACT

A display device includes a lower substrate, a bonding electrode disposed on the lower substrate, and a light emitting element disposed on the bonding electrode. The bonding electrode includes a first bonding metal layer and a second bonding metal layer sequentially disposed on the lower substrate, each including a bonding metal, a third bonding metal layer disposed between the first bonding metal layer and the second bonding metal layer, and including the bonding metal, a first thin film layer disposed between the first bonding metal layer and the third bonding metal layer, and a second thin film layer disposed between the second bonding metal layer and the third bonding metal layer, and the first thin film layer and the second thin film layer include a material with an atomic volume that is greater than or equal to about 80% of an atomic volume of the bonding metal.

### CROSS-REFERENCE TO RELATED APPLICATION

This application claims priority to and benefits of Korean Patent Application No. 10-2024-0061324 under 35 U.S.C. § 119, filed on May 9, 2024 in the Korean Intellectual Property Office, the entire contents of which are incorporated herein by reference.

### BACKGROUND

### 1. Technical Field

The disclosure relates to a display device and a method of manufacturing the same, and an electronic device for providing an image.

### 2. Description of the Related Art

As society becomes more information-orientated, increasing demands are placed on display devices to display images in various ways. In line with this trend, various types of display devices, including light emitting display devices, are being developed. A light emitting display device may include a pixel that includes a light emitting element.

### SUMMARY

Aspects of the disclosure provide a display device that may enhance manufacturing efficiency and a method for manufacturing the same, and an electronic device for providing an image.

According to an aspect of the disclosure, a display device is provided, including a lower substrate, a bonding electrode disposed on the lower substrate, and a light emitting element disposed on the bonding electrode. The bonding electrode may include a first bonding metal layer and a second bonding metal layer sequentially disposed on the lower substrate, each including a bonding metal, a third bonding metal layer disposed between the first bonding metal layer and the second bonding metal layer, also including the bonding metal, a first thin film layer disposed between the first bonding metal layer and the third bonding metal layer, and a second thin film layer disposed between the second bonding metal layer and the third bonding metal layer. The first thin film layer and the second thin film layer may include a material with an atomic volume that is greater than or equal to about 80% of an atomic volume of the bonding metal.

In an embodiment, the first bonding metal layer, the second bonding metal layer, and the third bonding metal layer may include at least one of titanium (Ti), zirconium (Zr), nickel (Ni), or chromium (Cr).

In an embodiment, the first thin film layer and the second thin film layer may include at least one of gold (Au), zirconium (Zr), silver (Ag), hafnium (Hf), palladium (Pd), or platinum (Pt).

In an embodiment, the first bonding metal layer, the second bonding metal layer, and the third bonding metal layer may include titanium (Ti), and the first thin film layer and the second thin film layer may include at least one of gold (Au), or zirconium (Zr).

In an embodiment, each of the first bonding metal layer and the second bonding metal layer may have a thickness in a range of about 100 nm to about 300 nm.

In an embodiment, a thickness of the third bonding metal layer may be less than or equal to the thickness of each of the first bonding metal layer and the second bonding metal layer.

In an embodiment, each of the first thin film layer and the second thin film layer may have a thickness in a range of about 1 nm to about 50 nm.

In an embodiment, the bonding electrode may further include a bonding layer disposed between the lower substrate and the first bonding metal layer.

In an embodiment, the bonding electrode may further include a reflective layer disposed between the second bonding metal layer and the light emitting element.

In an embodiment, the lower substrate may further include a semiconductor substrate including a pixel circuit, a connection electrode that connects the pixel circuit to the bonding electrode, and a first insulating layer disposed on the semiconductor substrate and surrounding the connection electrode.

In an embodiment, the light emitting element may include a first semiconductor layer, a light emitting layer, and a second semiconductor layer, which are sequentially disposed on the bonding electrode.

In an embodiment, the display device may further include a second insulating layer surrounding a side surface of the light emitting element, and a common electrode disposed on the light emitting element.

In an embodiment, the display device may further include a reflection film surrounding the side surface of the light emitting element.

According to an aspect of the disclosure, a method of manufacturing a display device is provided, including, preparing a first substrate including a semiconductor circuit substrate, with a first bonding metal layer and a first thin film layer sequentially disposed on the semiconductor circuit substrate, preparing a second substrate including a semiconductor substrate, with an epi-layer, a second bonding metal layer, and a second thin film layer sequentially disposed on the semiconductor substrate, disposing the second substrate on the first substrate such that the first thin film layer and the second thin film layer face each other, and bonding the first substrate to the second substrate, separating the semiconductor substrate from the epi-layer, and forming a bonding electrode and a light emitting element by etching a lower bonding layer including the first bonding metal layer and the first thin film layer, the epi-layer, and an upper bonding layer including the second bonding metal layer and the second thin film layer. The first bonding metal layer and the second bonding metal layer may include a bonding metal, and the first thin film layer and the second thin film layer may include a material with an atomic volume that is greater than or equal to about 80% of an atomic volume of the bonding metal.

In an embodiment, the first bonding metal layer and the second bonding metal layer may include at least one of titanium (Ti), zirconium (Zr), nickel (Ni), or chromium (Cr).

In an embodiment, the first thin film layer and the second thin film layer may include at least one of gold (Au), zirconium (Zr), silver (Ag), hafnium (Hf), palladium (Pd), or platinum (Pt).

In an embodiment, the first bonding metal layer and the second bonding metal layer may include titanium (Ti), and the first thin film layer and the second thin film layer may include at least one of gold (Au), or zirconium (Zr).

In an embodiment, the bonding of the first substrate to the second substrate may include forming a third bonding metal layer including the bonding metal between the first thin film layer and the second thin film layer.

In an embodiment, each of the first bonding metal layer and the second bonding metal layer may have a thickness in a range of about 100 nm to about 300 nm.

In an embodiment, each of the first thin film layer and the second thin film layer may have a thickness in a range of about 1 nm to about 50 nm.

According to an aspect of the disclosure, an electronic device for providing an image is provided, including a display device. The display device may include a lower substrate, a bonding electrode disposed on the lower substrate, and a light emitting element disposed on the bonding electrode. The bonding electrode may include a first bonding metal layer and a second bonding metal layer sequentially disposed on the lower substrate, each including a bonding metal, a third bonding metal layer disposed between the first bonding metal layer and the second bonding metal layer, also including the bonding metal, a first thin film layer disposed between the first bonding metal layer and the third bonding metal layer, and a second thin film layer disposed between the second bonding metal layer and the third bonding metal layer. The first thin film layer and the second thin film layer may include a material with an atomic volume that is greater than or equal to about 80% of an atomic volume of the bonding metal.

According to the display device and the method of manufacturing the same, the diffusion of bonding metals may be promoted by forming thin film layers on bonding metal layers of a first substrate and a second substrate. Accordingly, the first substrate and the second substrate may be bonded smoothly without requiring a planarization process for the bonding metal layers. In embodiments, the manufacturing efficiency of the display device formed from the first substrate and the second substrate may be enhanced.

However, the effects according to the embodiments of the disclosure are not limited to those described above, and various other effects are also contemplated.

### BRIEF DESCRIPTION OF THE DRAWINGS

The above and other aspects, features, and advantages of embodiments of the disclosure will become more apparent from the following descriptions in conjunction with the accompanying drawings, in which:

FIG. 1 is a schematic perspective view illustrating a display device according to an embodiment;

FIG. 2 is a schematic plan view showing an example of area A1 of FIG. 1;

FIG. 3 is a schematic cross-sectional view illustrating a display panel according to an embodiment;

FIG. 4 is a schematic cross-sectional view showing an example of area A2 of FIG. 3;

FIGS. 5 to 10 are schematic perspective views showing a method for manufacturing the display device according to an embodiment;

FIGS. 11 to 18 are schematic cross-sectional views illustrating a method for manufacturing the display device according to an embodiment;

FIG. 19 is a schematic diagram illustrating a smart watch including a display device according to an embodiment;

FIGS. 20 and 21 are schematic diagrams illustrating a virtual reality device including a display device according to an embodiment;

FIG. 22 is a schematic diagram illustrating a virtual reality device including a display device according to another embodiment;

FIG. 23 is a schematic diagram illustrating a dashboard and a center fascia of an automobile, both including display devices according to an embodiment; and

FIG. 24 is a schematic diagram illustrating a transparent display device including a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implement in another embodiment.

In the drawings, sizes, thicknesses, ratios, and dimensions of elements may be exaggerated for ease of description and for clarity. Like reference numbers and/or reference characters refer to like elements throughout.

As used herein, the singular forms “a,” “an,” and “the” are intended to include the plural forms as well, unless the context clearly indicates otherwise.

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction.”

In a case that an element, such as a layer, a region, a portion, or the like, is referred to as being “on,” “connected to,” or “coupled to” another element or layer, it may be directly on, connected to, or coupled to the other element or layer or intervening elements or layers may be present. However, in a case that an element or layer is referred to as being “directly on,” “directly connected to,” or “directly coupled to” another element or layer, there are no intervening elements or layers present. To this end, the term “connected” may refer to physical and/or electrical connection, with or without intervening elements.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Features of various embodiments of the disclosure may be partially or entirely combined and may interwork in different technical ways. Each embodiment may be implemented independently or in combination with other embodiments.

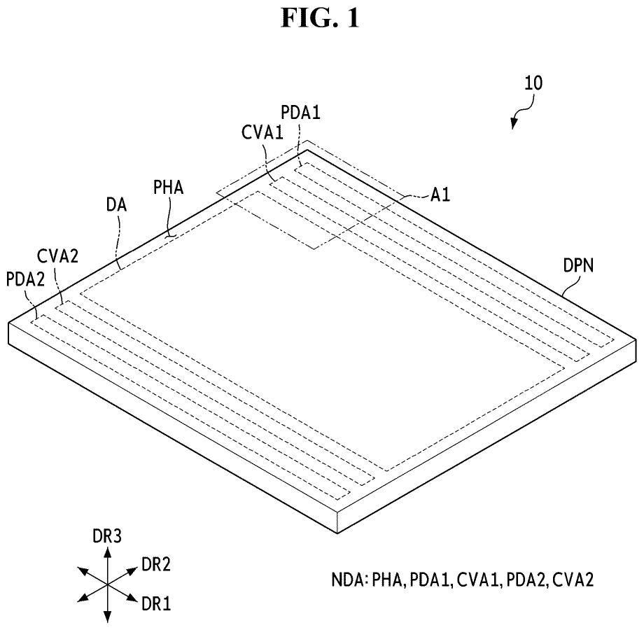

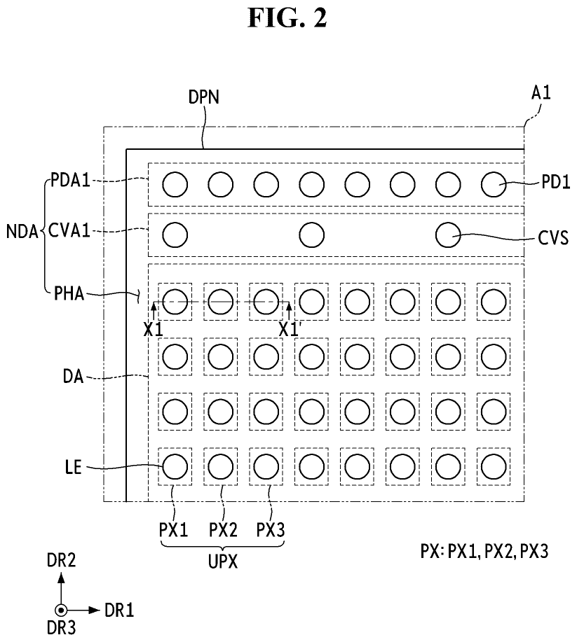

FIG. 1 is a schematic perspective view illustrating a display device according to an embodiment. FIG. 2 is a schematic plan view showing an example of area A1 of FIG. 1.

Referring to FIGS. 1 and 2, a display device 10 according to an embodiment may include a display panel DPN, which includes a display area DA and a non-display area NDA. In an embodiment, the display device 10 may be included in or provided with an electronic device. For example, the display device 10 may be included in or provided with one of various types of electronic devices for providing an image. Alternatively, the display device 10 may be provided alone.

The display panel DPN may have a quadrilateral planar shape having long sides in a first direction DR1 and short sides in a second direction DR2. In FIGS. 1 and 2, the first direction DR1 may refer to a horizontal direction (or vertical direction) of the display panel DPN, while the second direction DR2 may refer to a vertical direction (or horizontal direction) of the display panel DPN. A third direction DR3 may refer to a thickness direction or a height direction of the display panel DPN. However, the planar shape of the display panel DPN is not limited to a quadrilateral shape, and the display panel DPN may have a different shape. For example, the display panel DPN may include a polygonal shape, a circular shape, an elliptical shape, or an irregular shape in a plan view.

The display area DA may be where images are displayed, while the non-display area NDA may be where no images are displayed. In an embodiment, the planar shape of the display area DA may follow the planar shape of the display panel DPN. FIG. 1 illustrates an embodiment in which the display area DA has a quadrilateral planar shape. The display area DA may be disposed in a central area of the display panel DPN, while the non-display area NDA may be disposed around the display area DA. For example, the non-display area NDA may surround the display area DA.

The display panel DPN may include multiple pixels PX arranged in the display area DA. For example, the display panel DPN may include first pixels PX1 emitting light of a first color, second pixels PX2 emitting light of a second color, and third pixels PX3 emitting light of a third color. In an embodiment, the first color may be red, the second color may be green, and the third color may be blue, but they are not limited to these colors. At least one first pixel PX1, at least one second pixel PX2, and at least one third pixel PX3 adjacent to each other may form each unit pixel UPX, capable of emitting light of various colors. For example, the first pixel PX1, the second pixel PX2, and the third pixel PX3, disposed adjacent to each other in a K-th (K is a natural number) row of the display area DA, may form one unit pixel UPX. The number, type, and/or arrangement of the pixels PX forming the unit pixel UPX may vary depending on the embodiments.

Each pixel PX may include at least one light emitting element LE. For example, each pixel PX may include a single light emitting element LE or may include multiple light emitting elements LE.

The light emitting elements LE may have a circular shape, a quadrilateral shape, or another planar shape. For example, the shape of the light emitting elements LE may vary depending on the embodiments.

In an embodiment, the light emitting element LE may be a micro light emitting diode (micro LED) having a small size in the micrometer (μm) range. For example, each light emitting element LE may be a micro LED having a length (e.g., horizontal length) in the first direction DR1, a length (e.g., vertical length) in the second direction DR2, and a length (e.g., thickness or height) in the third direction DR3, which each dimension is several to hundreds of micrometers. In an embodiment, the length of the light emitting element LE in the first direction DR1, the second direction DR2, and the third direction DR3 may be approximately less than or equal to 100 μm, but is not limited to this dimension.

In an embodiment, the first pixels PX1, the second pixels PX2, and the third pixels PX3 may include light emitting elements LE that emit light of the first color, light of the second color, and light of the third color, respectively. In another embodiment, the first pixels PX1, the second pixels PX2, and the third pixels PX3 may include light emitting elements LE that emit light of the same color, and light conversion patterns (e.g., wavelength conversion patterns including quantum dots) and/or color filters may be disposed in the emission areas of the first pixels PX1, the second pixels PX2, and/or the third pixels PX3 to convert or control the color of light emitted from the light emitting elements LE provided in each pixel PX.

In an embodiment, the pixels PX may be arranged in the display area DA in a matrix form, a stripe form, or any other form. The sizes of the pixels PX (or the emission areas of the pixels PX) may be substantially the same or different from each other.

In an embodiment, the pixels PX may have a quadrilateral planar shape, such as a rectangular shape or a rhombic shape, but the disclosure is not limited thereto. For example, the pixels PX may have another polygonal shape (e.g., a hexagonal shape or diamond shape), a circular shape, an elliptical shape, or other planar shapes.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA. The second common voltage supply area CVA2 may be disposed between the second pad area PDA2 and the display area DA. Each of the first common voltage supply area CVA1 and the second common voltage supply area CVA2 may include common electrode connection portions CVS that are electrically connected to a common electrode of the pixels PX, a second pixel power line, or the like. A second pixel voltage (e.g., a common voltage) may be supplied to the pixels PX through the common electrode connection portions CVS.

The common electrode connection portions CVS may be disposed in a common voltage supply area (e.g., the first common voltage supply area CVA1 and/or the second common voltage supply area CVA2) of the non-display area NDA. The common electrode connection portions CVS may include a conductive material (e.g., a metal material such as aluminum (Al)). FIGS. 1 and 2 illustrate the display device 10 in which the common electrode connection portions CVS are positioned in the non-display area NDA, but the embodiments are not limited thereto. For example, the common electrode connection portions CVS may be located in the display area DA.

The common electrode connection portions CVS of the first common voltage supply area CVA1 may be electrically connected to any one of first pads PD1 in the first pad area PDA1. For example, the common electrode connection portions CVS of the first common voltage supply area CVA1 may receive a second pixel voltage (e.g., a common voltage) from any one of the first pads PD1 in the first pad area PDA1.

The first pads PD1 may be disposed in the first pad area PDA1. The first pads PD1 may be connected to a circuit board (not shown) through a conductive connection member. For example, the first pads PD1 may be electrically connected to a circuit pad provided on a circuit board through a wire.

The common electrode connection portions CVS of the second common voltage supply area CVA2 may be electrically connected to any one of second pads of the second pad area PDA2. For example, the common electrode connection portions CVS of the second common voltage supply area CVA2 may receive a second pixel voltage (e.g., a common voltage) from any one of the second pads in the second pad area PDA2. In an embodiment, the display panel DPN may not include the second common voltage supply area CVA2.

The first pad area PDA1 may be disposed on a side (e.g., an upper side) of the display panel DPN. The first pad area PDA1 may include the first pads PD1, which are connected to an external circuit board.

The second pad area PDA2 may be disposed on a side (e.g., a lower side) of the display panel DPN. The second pad area PDA2 may include the second pads connected to an external circuit board. In an embodiment, the display panel DPN may not include the second pad area PDA2.

The second pads may be disposed in the second pad area PDA2 of the non-display area NDA. The second pads may be connected to a circuit board (not shown) through a conductive connection member. For example, the second pads may be electrically connected to the circuit pads provided on the circuit board through wires.

The peripheral area PHA may be the remaining portion of the non-display area NDA, except for the first common voltage supply area CVA1, the second common voltage supply area CVA2, the first pad area PDA1, and the second pad area PDA2. The peripheral area PHA may surround not only the display area DA, but also the first common voltage supply area CVA1, the second common voltage supply area CVA2, the first pad area PDA1, and the second pad area PDA2.

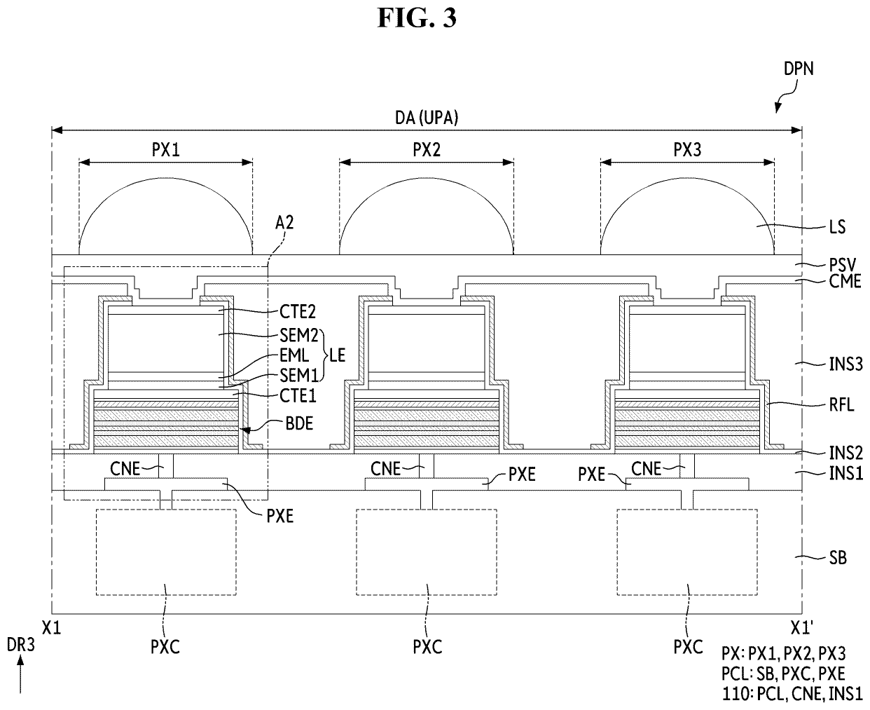

FIG. 3 is a schematic cross-sectional view illustrating a display panel according to an embodiment. For example, FIG. 3 shows an embodiment of a cross section of the display panel DPN corresponding to line X1-X1′ of FIG. 2, which is a schematic cross section of the first pixel PX1, the second pixel PX2, and the third pixel PX3 located in a unit pixel area UPA of the display area DA.

FIG. 3 illustrates an embodiment in which the display device 10 is a light emitting diode on silicon (LEDoS) in which light emitting diodes are disposed as the light emitting elements LE on a semiconductor circuit substrate PCL, formed by a semiconductor process using a silicon wafer. However, the device including light emitting elements LE according to embodiments is not limited to this configuration. For example, the light emitting elements LE manufactured according to embodiments may be applied to display devices of various types and/or structures or may be applied to devices of different types and/or structures, such as lighting devices.

Referring to FIGS. 1 to 3, the display panel DPN may include a semiconductor circuit substrate PCL (or thin film transistor substrate), connection electrodes CNE and a first insulating layer INS1 disposed on the semiconductor circuit substrate PCL, bonding electrodes BDE disposed on the connection electrodes CNE and the first insulating layer INS1, and the light emitting elements LE disposed on the bonding electrodes BDE. In an embodiment, the display panel DPN may further include at least one of contact electrodes CTE1 and CTE2 disposed on at least one surface of the light emitting elements LE, a second insulating layer INS2, a reflection film RFL, and a third insulating layer INS3 surrounding the side surfaces or other areas of the light emitting elements LE, or a common electrode CME and a passivation layer PSV disposed on the light emitting elements LE. In an embodiment, the display panel DPN may further include an optical structure (or emission structure) disposed on the passivation layer PSV, for example, a lens-type optical structure LS. Although not illustrated in FIG. 3, the display panel DPN may further include a protective layer covering the lens-type optical structure LS or the like.

The semiconductor circuit substrate PCL may include the display area DA in which the pixel circuits PXC of the pixels PX are formed. The semiconductor circuit substrate PCL may further include the non-display area NDA, as illustrated in FIGS. 1 and 2. For example, the semiconductor circuit substrate PCL may include the common electrode connection portions CVS, the first pads PD1, and/or the second pads disposed in the non-display area NDA.

The semiconductor circuit substrate PCL may include the base substrate SB, the pixel circuits PXC disposed or formed on the base substrate SB, and the pixel electrodes PXE (or connection lines) connected to the respective pixel circuits PXC. The semiconductor circuit substrate PCL may further include wires connected to the pixels PX. For example, the semiconductor circuit substrate PCL may further include signal lines and power lines (e.g., a first pixel power line to which a first pixel voltage is applied, and a second pixel power line for applying a second pixel voltage) connected to the pixel circuits PXC. In describing embodiments, the term “connect” may refer to both electrical connection and/or physical connection.

In an embodiment, the semiconductor circuit substrate PCL may be formed through a semiconductor process using a silicon wafer. For example, the base substrate SB may be a silicon wafer. In an embodiment, the base substrate SB may be made of monocrystalline silicon.

The pixel circuits PXC may be disposed on the semiconductor circuit substrate PCL to correspond to the corresponding unit pixel areas UPA where the respective pixels PX are disposed. In an embodiment, each of the pixel circuits PXC may include a complementary metal oxide semiconductor (CMOS) circuit formed using a semiconductor process. In an embodiment, each of the pixel circuits PXC may include at least one transistor and at least one capacitor, both formed through a semiconductor process. FIG. 3 illustrates schematic positions of the pixel circuits PXC provided in the first pixel PX1, the second pixel PX2, and the third pixel PX3 as an example of elements provided on the semiconductor circuit substrate PCL.

The pixel electrodes PXE may be disposed on the respective pixel circuits PXC. The pixel electrodes PXE may be connected to the respective pixel circuits PXC. For example, the pixel circuit PXC of each pixel PX may be electrically connected to the pixel electrode PXE of the corresponding pixel PX. The pixel electrode PXE may receive a first pixel voltage or an anode voltage from the pixel circuits PXC.

In an embodiment, the pixel electrodes PXE1 may be formed integrally with the respective pixel circuits PXC. For example, the pixel electrodes PXE may be exposed electrodes (or wires) that protrude from the top surfaces of the respective pixel circuits PXC.

The pixel electrodes PXE may include at least one conductive material. For example, the pixel electrodes PXE may include, but are not limited to, copper (Cu), titanium (Ti), silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or a mixture thereof.

The pixel electrodes PXE may be connected to the light emitting elements LE through the connection electrodes CNE and the bonding electrodes BDE. As an example, the pixel electrode PXE of each of the pixels PX may be electrically connected to the light emitting element LE on the bonding electrode BDE through the connection electrode CNE and the bonding electrode BDE of the corresponding pixel PX.

The first insulating layer INS1 may be disposed on the pixel circuits PXC and the pixel electrodes PXE. The first insulating layer INS1 may include openings (e.g., contact holes or via holes) that partially expose the pixel electrodes PXE. The openings may be filled with the connection electrodes CNE. For example, the first insulating layer INS1 may surround the connection electrodes CNE.

The first insulating layer INS1 may include at least one insulating material and may have a single-layer or multilayer structure. In an embodiment, the first insulating layer INS1 may include an inorganic insulating material (e.g., silicon oxide (SiOₓ), silicon nitride (SiNₓ), aluminum oxide (AlₓO_{y}), titanium oxide (TiₓO_{y}), hafnium oxide (HfOₓ), or other inorganic insulating materials), but is not limited thereto.

The connection electrodes CNE may connect the semiconductor circuit substrate PCL to the bonding electrodes BDE. For example, the connection electrodes CNE may connect (e.g., electrically connect) the pixel circuit PXC of each of the pixels PX to the bonding electrode BDE. As an example, the connection electrodes CNE may be connected between the pixel electrode PXE of each of the pixels PX and the bonding electrode BDE.

The connection electrodes CNE may include a conductive metal. For example, the connection electrodes CNE may include at least one of gold (Au), copper (Cu), tin (Sn), titanium (Ti), aluminum (Al), or silver (Ag).

The semiconductor circuit substrate PCL, the connection electrodes CNE, and the first insulating layer INS1 may form a lower substrate 110 (e.g., backplane substrate) of the display panel DPN. The bonding electrodes BDE, the light emitting elements LE, and the like may be disposed on the lower substrate 110.

The bonding electrodes BDE may be disposed on the first insulating layer INS1. The bonding electrodes BDE may be separated from each other in corresponding unit pixel areas UPA where the pixels PX are disposed. Accordingly, the light emitting elements LE of the pixels PX may be individually controlled. Each of the bonding electrodes BDE may be connected to the connection electrode CNE of the corresponding pixel PX. In an embodiment, the bonding electrode BDE may function as an anode electrode (or cathode electrode) of the light emitting element LE or the pixel PX.

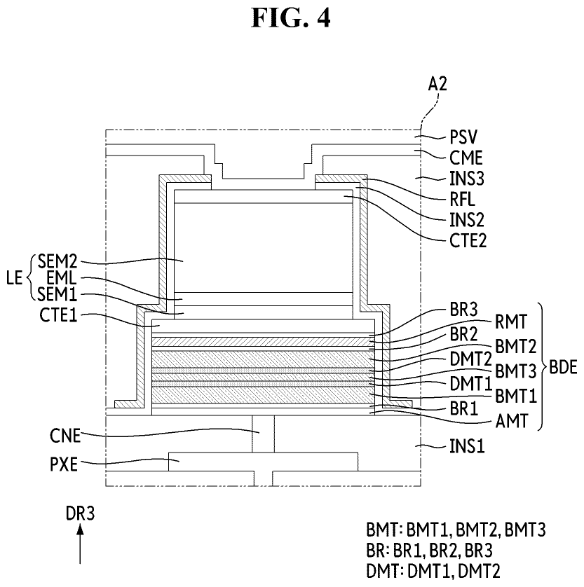

Bonding electrodes BDE may include multilayer metal layers. For example, the bonding electrodes BDE may include multiple bonding metal layers and thin film layers disposed between the bonding metal layers. Embodiments related to the structure, materials, or the like of the bonding electrodes BDE will be described later with reference to FIG. 4.

In an embodiment, the first contact electrode CTE1 may be disposed on each of the bonding electrodes BDE, and the light emitting element LE may be disposed on the first contact electrode CTE1. In FIG. 3, the first contact electrode CTE1 is illustrated as a separate component from the light emitting element LE, but the embodiments are not limited thereto. For example, the first contact electrode CTE1 may be regarded as a component included in the light emitting element LE. The first contact electrode CTE1 may be formed or etched together with the light emitting element LE, or may be formed or etched separately from the light emitting element LE.

In another embodiment, the light emitting element LE or the pixel PX may not include the first contact electrode CTE1. The light emitting element LE may be disposed directly on the bonding electrode BDE of the pixel PX.

The first contact electrode CTE1 may be disposed on a surface (e.g., bottom surface) of a first semiconductor layer SEM1. The first contact electrode CTE1 may protect the first semiconductor layer SEM1 and may smoothly connect the light emitting element LE to the bonding electrode BDE.

In an embodiment, the first contact electrode CTE1 may be entirely disposed on a surface of the first semiconductor layer SEM1. For example, the first contact electrode CTE1 may be entirely disposed on the bottom surface of the first semiconductor layer SEM1. Accordingly, the first semiconductor layer SEM1 may be appropriately or stably protected. However, the embodiments are not limited thereto, and the first contact electrode CTE1 may be disposed only on a portion of the first semiconductor layer SEM1.

The first contact electrode CTE1 may include metal, metal oxide, or other conductive materials. In an embodiment, the first contact electrode CTE1 may be formed of a transparent electrode layer that includes a transparent conductive material (e.g., indium tin oxide (ITO), indium zinc oxide (IZO), or another transparent conductive material), but is not limited thereto.

Each of the light emitting elements LE may be disposed on the first contact electrode CTE1 (or the bonding electrode BDE) of the corresponding pixel PX.

Each of the light emitting elements LE may include the first semiconductor layer SEM1, the light emitting layer EML, and the second semiconductor layer SEM2 sequentially disposed on the first contact electrode CTE1. For example, the first semiconductor layer SEM1, the light emitting layer EML, and the second semiconductor layer SEM2 may be sequentially disposed or stacked on the first contact electrode CTE1 along the third direction DR3. The first semiconductor layer SEM1, the light emitting layer EML, and the second semiconductor layer SEM2 may include the same semiconductor material and may be formed from a semiconductor thin film layer (semiconductor epitaxial stack) or epi-layers formed by epitaxial growth on a semiconductor substrate.

The first semiconductor layer SEM1 may include a semiconductor material doped with a first conductivity-type dopant. For example, the first semiconductor layer SEM1 may be a semiconductor layer of a first conductivity-type that includes a nitride-based semiconductor material, a phosphide-based semiconductor material, or another semiconductor material, and that further includes a dopant of a first conductivity type. In an embodiment, the first semiconductor layer SEM1 may be a p-type semiconductor layer (e.g., p-GaN) doped with a p-type dopant such as Mg, Zn, Ca, Se, and Ba, but is not limited thereto.

The light emitting layer EML may be disposed on the first semiconductor layer SEM1. For example, the light emitting layer EML may be disposed between the first semiconductor layer SEM1 and the second semiconductor layer SEM2. The light emitting layer EML may emit light by recombination of electron-hole pairs generated in response to an electrical signal applied through the first semiconductor layer SEM1 and the second semiconductor layer SEM2.

The light emitting layer EML may include a nitride-based semiconductor material, a phosphide-based semiconductor material, or another semiconductor material, and may have a single or multiple quantum well structure. In an embodiment, the light emitting layer EML may have a multiple quantum well structure, including a quantum well layer including InGaN and a barrier layer including GaN, AlGaN, or GaAlN, but is not limited thereto. In an embodiment, in the case where the light emitting layer EML includes InGaN, the color of light emitted from the light emitting layer EML may be adjusted by varying the content of indium (In).

In an embodiment, the light emitting layer EML may emit light in a visible light wavelength band, for example, light in a wavelength band of approximately 400 nm to 900 nm. For example, the light emitting layer EML may emit blue light having a peak wavelength in a range of approximately 440 nm to 480 nm, green light having a peak wavelength in a range of approximately 510 nm to 550 nm, or red light having a peak wavelength in a range of approximately 610 nm to 650 nm. The light emitting layer EML may emit light of a different color or wavelength band than the color or the wavelength band described above.

The second semiconductor layer SEM2 may include a semiconductor material doped with a second conductivity-type dopant. For example, the second semiconductor layer SEM2 may be a semiconductor layer of a second conductivity-type that includes a nitride-based semiconductor material, a phosphide-based semiconductor material, or another semiconductor material, and further includes a dopant of a second conductivity-type. In an embodiment, the second semiconductor layer SEM2 may be an n-type semiconductor layer (e.g., n-GaN) doped with an n-type dopant such as Si, Ge, and Sn, but is not limited thereto.

In an embodiment, the second contact electrode CTE2 may be disposed on each of the light emitting elements LE, and the common electrode CME may be disposed on the second contact electrode CTE2. For example, the second semiconductor layer SEM2 of the light emitting element LE may be electrically connected to the common electrode CME through the second contact electrode CTE2.

In FIG. 3, the second contact electrode CTE2 is illustrated as a separate component from the light emitting element LE, but the embodiments are not limited thereto. For example, the second contact electrode CTE2 may be regarded as a component included in the light emitting element LE. The second contact electrode CTE2 may be formed or etched together with the light emitting element LE, or may be formed or etched separately from the light emitting element LE.

In another embodiment, the light emitting element LE or the pixel PX may not include the second contact electrode CTE2. The common electrode CME may be disposed directly on the light emitting element LE. For example, in the case where the light emitting element LE or the pixel PX does not include the second contact electrode CTE2, the second semiconductor layer SEM2 of the light emitting element LE may directly contact the common electrode CME.

The second contact electrode CTE2 may be disposed on a surface (e.g., top surface) of the second semiconductor layer SEM2. The second contact electrode CTE2 may protect the second semiconductor layer SEM2 and may smoothly connect the light emitting element LE to the common electrode CME.

In an embodiment, the second contact electrode CTE2 may be entirely disposed on a surface of the second semiconductor layer SEM2. For example, the second contact electrode CTE2 may be entirely disposed on the top surface of the second semiconductor layer SEM2. Accordingly, the second semiconductor layer SEM2 may be appropriately or stably protected. However, the embodiments are not limited thereto, and the second contact electrode CTE2 may be disposed only on a portion of the second semiconductor layer SEM2.

The second contact electrode CTE2 may include metal, metal oxide, or other conductive materials. In an embodiment, the second contact electrode CTE2 may be formed of a transparent electrode layer that includes a transparent conductive material (e.g., indium tin oxide (ITO), indium zinc oxide (IZO), or another transparent conductive material). Accordingly, light generated in the light emitting element LE may pass through the second contact electrode CTE2 and be emitted to the upper side of the light emitting element LE.

The light emitting elements LE may be surrounded by the second insulating layer INS2 or the like. For example, a side surface of each of the light emitting elements LE may be surrounded by the second insulating layer INS2 and the reflection film RFL.

The second insulating layer INS2 may surround the side surfaces of the light emitting elements LE. In an embodiment, the second insulating layer INS2 may further surround the side surface of at least one of the bonding electrodes BDE, the first contact electrode CTE1, or the second contact electrode CTE2. As an example, the second insulating layer INS2 may be entirely disposed in the display area DA to surround the side surfaces of the light emitting elements LE, the bonding electrodes BDE, the first contact electrode CTE1, and the second contact electrode CTE2, and may include an opening that exposes a portion (e.g., a portion of the top surface) of each of the light emitting elements LE or the second contact electrode CTE2. In the opened portion of the second insulating layer INS2, the light emitting element LE or the second contact electrode CTE2 may be connected to the common electrode CME.

The second insulating layer INS2 may include at least one insulating material such as silicon oxide (SiOₓ) (e.g., SiO₂), silicon nitride (SiNₓ) (e.g., Si₃N₄), aluminum oxide (AlₓO_{y}) (e.g., Al₂O₃), titanium oxide (TiₓO_{y}) (e.g., TiO₂), and hafnium oxide (HfOₓ), or another insulating material. The second insulating layer INS2 may protect the light emitting elements LE and the like, and may ensure or improve the electrical characteristics of the light emitting elements LE by preventing short circuit defects in the light emitting elements LE.

The reflection film RFL may be disposed on the second insulating layer INS2. The reflection film RFL may surround the side surface of each of the light emitting elements LE. In an embodiment, the reflection film RFL may further surround the side surface of at least one of the bonding electrodes BDE, the first contact electrode CTE1, or the second contact electrode CTE2. The reflection film RFL may be individually disposed in each unit pixel area UPA or may cover the entire display area DA, and may include an opening that exposes a portion (e.g., at least a portion of the top surface) of each of the light emitting elements LE or the second contact electrode CTE2.

The reflection film RFL may be formed in each of the light emitting elements LE and may reflect and recycle light directed in the lateral direction or the like. The light emission efficiency (e.g., the ratio of light transmitted through the second contact electrode CTE2, the common electrode CME, or the like and emitted from the upper side of the light emitting element LE) of each of the light emitting elements LE may be increased by the reflection film RFL.

The reflection film RFL may include a metal material with high reflectivity, such as aluminum (Al). In another embodiment, the reflection film RFL may include at least one pair (e.g., two or more pairs) of a first layer and a second layer having different refractive indices and disposed alternately, and thus may function as distributed Bragg reflectors (DBR). The first layer and the second layer may be formed of an inorganic material, such as silicon nitride (SiNₓ), silicon oxynitride (SiOₓN_{y}), silicon oxide (SiOₓ), titanium oxide (TiₓO_{y}), aluminum oxide (AlₓO_{y}), or the like.

The third insulating layer INS3 may be disposed around the light emitting elements LE. As an example, the third insulating layer INS3 may fill the space between the light emitting elements LE to surround the emission areas in which the light emitting elements LE are positioned. For example, the third insulating layer INS3 may act as a filler, filling or occupying the gap between the light emitting elements LE.

The third insulating layer INS3 may be a single layer or multiple layers that include at least one insulating material. In an embodiment, the third insulating layer INS3 may include silicon oxide (SiOₓ), silicon nitride (SiNₓ), silicon oxynitride (SiOₓN_{y}), aluminum oxide (AlₓO_{y}), titanium oxide (TiₓO_{y}), hafnium oxide (HfOₓ), or other inorganic insulating materials. In an embodiment, the third insulating layer INS3 may have a thickness sufficient to have a substantially flat top surface, or may have a substantially flat top surface through a planarization process performed after film formation. In another embodiment, the third insulating layer INS3 may include at least one organic insulating layer including an organic material, and the top surface of the third insulating layer INS3 may be substantially flat. For example, the third insulating layer INS3 may be a single-layer or multilayer organic insulating layer including acrylic resin, epoxy resin, phenolic resin, polyamide resin, and polyimide resin, or other organic insulating materials.

The third insulating layer INS3 may expose a portion, for example, the top surface, of the light emitting elements LE. In an embodiment, the third insulating layer INS3 may have a height greater than or equal to the height of the light emitting elements LE and may be opened at the top of each of the light emitting elements LE. In another embodiment, the third insulating layer INS3 may have a height that is less than or equal to the height of the light emitting elements LE. In an embodiment, the third insulating layer INS3 may have a height similar to the height of the light emitting elements LE. Accordingly, the stepped portion of the common electrode CME may be alleviated, preventing disconnection of the common electrode CME.

The common electrode CME may be disposed on both the light emitting elements LE and the third insulating layer INS3. For example, the common electrode CME may cover the entire display area DA. The common electrode CME may contact the second contact electrodes CTE2 (or the light emitting elements LE) at the opened portion of the third insulating layer INS3. For example, the common electrode CME may be a common layer formed and/or connected to the light emitting elements LE of the display area DA and the pixels PX included therein.

The common electrode CME may be electrically connected to the common electrode connection portions CVS disposed in the first common voltage supply area CVA1 and/or the second common voltage supply area CVA2 of FIGS. 1 and 2. Thus, the common electrode CME may receive a common voltage through the common electrode connection portions CVS. In an embodiment, the common electrode CME may be connected to a power line (e.g., a second pixel power line) formed on the semiconductor circuit substrate PCL within and/or around the display area DA. The connection structure between the common electrode CME and the common electrode connection portions CVS may vary depending on embodiments.

The common electrode CME may include a transparent conductive material capable of transmitting light. For example, the common electrode CME may be made of indium tin oxide (ITO), indium zinc oxide (IZO), or other transparent conductive materials. In an embodiment, it may function as a cathode electrode (or anode electrode) of the light emitting elements LE or pixels PX.

The passivation layer PSV may be disposed on the common electrode CME. In an embodiment, the passivation layer PSV may include a capping layer that covers the entire display area DA to protect the common electrode CME. The capping layer may include an inorganic insulating material such as silicon oxide (SiOₓ), silicon nitride (SiNₓ), silicon oxynitride (SiOₓN_{y}), aluminum oxide (AlₓO_{y}), and aluminum nitride (AlN), or other insulating materials. In another embodiment, the passivation layer PSV may further include an overcoat layer or the like covering the capping layer. The overcoat layer may include a material (e.g., a material that absorbs or relieves physical impact or the like on the display panel DPN) that provides appropriate protection of the display panel DPN. Additionally, the overcoat layer may flatten the top surface of the passivation layer PSV.

The lens-type optical structure LS may be disposed in the emission area of each of the pixels PX to overlap the light emitting elements LE. In an embodiment, the lens-type optical structure LS may be an optical structure in the form of a convex lens provided above the light emitting elements LE, but the type and/or form of the optical structure is not limited thereto. By disposing the lens-type optical structure LS above the light emitting elements LE, the light emission characteristics of the pixels PX may be adjusted and/or improved.

The lens-type optical structure LS may be formed of a transparent material to transmit light emitted from the light emitting elements LE. As an example, the lens-type optical structure LS may be formed of glass, plastic, ceramic, or other materials, and may be formed of an optical material with a high refractive index.

In an embodiment, the display panel DPN may include a protective layer covering the lens-type optical structure LS. As an example, the display panel DPN, which covers the entire display area DA, may further include a protective layer over the lens-type optical structure LS. The protective layer may be formed of a transparent and durable material (e.g., plastic, organic glass, optical glass, ceramic, or the like), and the material is not specifically limited as long as it is suitable for protecting the lens-type optical structure LS or the like.

In an embodiment, the display panel DPN or the display device 10 including the display panel DPN may also include additional components. For example, the display panel DPN or the display device 10 may include a light conversion layer (e.g., a light conversion layer including light conversion patterns disposed over the light emitting elements LE of the first pixels PX1, the second pixels PX2 and/or the third pixels PX3), or a color filter or the like, disposed above the pixels PX.

FIG. 4 is a schematic cross-sectional view showing an example of area A2 of FIG. 3. For example, FIG. 4 illustrates the detailed structure of a bonding electrode BDE in an embodiment.

Referring to FIG. 4, the bonding electrode BDE may include multiple layers including multiple bonding metal layers BMT. The respective layers forming the bonding electrode BDE may include a conductive material, thereby providing conductivity.

In an embodiment, the bonding metal layers BMT may include a first bonding metal layer BMT1 and a second bonding metal layer BMT2 sequentially disposed along the third direction DR3, with a third bonding metal layer BMT3 disposed between the first bonding metal layer BMT1 and the second bonding metal layer BMT2. Thin film layers DMT may be disposed between the bonding metal layers BMT. For example, the bonding electrode BDE may include a first thin film layer DMT1 disposed between the first bonding metal layer BMT1 and the third bonding metal layer BMT3, and a second thin film layer DMT2 disposed between the second bonding metal layer BMT2 and the third bonding metal layer BMT3.

In an embodiment, the bonding electrode BDE may further include additional layers. As an example, the bonding electrode BDE may include a bonding layer AMT (also referred to as an “adhesion layer”) disposed between the connection electrode CNE and the first bonding metal layer BMT1, as well as a reflective layer RMT disposed on the second bonding metal layer BMT2. In an embodiment, the bonding electrode BDE may further include at least one barrier layer BR. As an example, the bonding electrode BDE may include a first barrier layer BR1 disposed between the bonding layer AMT and the first bonding metal layer BMT1, and a second barrier layer BR2 and a third barrier layer BR3 disposed on both surfaces of the reflective layer RMT.

The first bonding metal layer BMT1, the second bonding metal layer BMT2, and the third bonding metal layer BMT3 may include a conductive material suitable for bonding. For example, the first bonding metal layer BMT1, the second bonding metal layer BMT2, and the third bonding metal layer BMT3 may include a metal or metal alloy with excellent electrical and thermal conductivity.

In an embodiment, the bonding metal layers BMT may include a metal or alloy that has properties suitable for bonding and presents a low risk of generating foreign matter during processes such as etching. As an example, the bonding metal layers BMT may include titanium (Ti). For example, the semiconductor substrate including the epi-layer (or the light emitting elements LE) used to form the light emitting elements LE, and the lower substrate 110 may be bonded by thermocompression bonding using titanium (Ti).

Titanium (Ti) has relatively high reactivity, which reduces the risk of foreign matter formation during an etching process (e.g., a wet etching process or the like), and it may act as a highly reliable conductive material due to its corrosion resistance. In the case where the bonding metal layers BMT are formed using titanium (Ti), the reliability of the bonding electrode BDE may be improved. However, the material of the bonding metal layers BMT is not limited to titanium (Ti). For example, the bonding metal layers BMT may include other highly reliable bonding metals such as zirconium (Zr), nickel (Ni), or chromium (Cr).

In an embodiment, the bonding metal layers BMT may include the same material. As an example, the first bonding metal layer BMT1, the second bonding metal layer BMT2, and the third bonding metal layer BMT3 may be metal layers including titanium (Ti) (e.g., made of titanium (Ti)).

In an embodiment, the first bonding metal layer BMT1 and the second bonding metal layer BMT2 may have a thickness suitable for bonding. For example, the thickness of each of the first bonding metal layer BMT1 and the second bonding metal layer BMT2 may range from about 100 nm to about 300 nm (e.g., about 200 nm), but is not limited to this range.

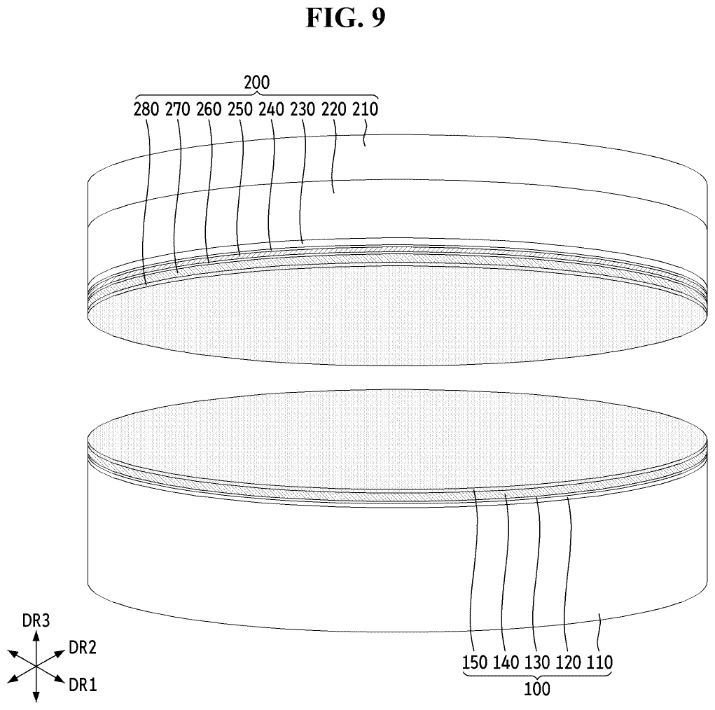

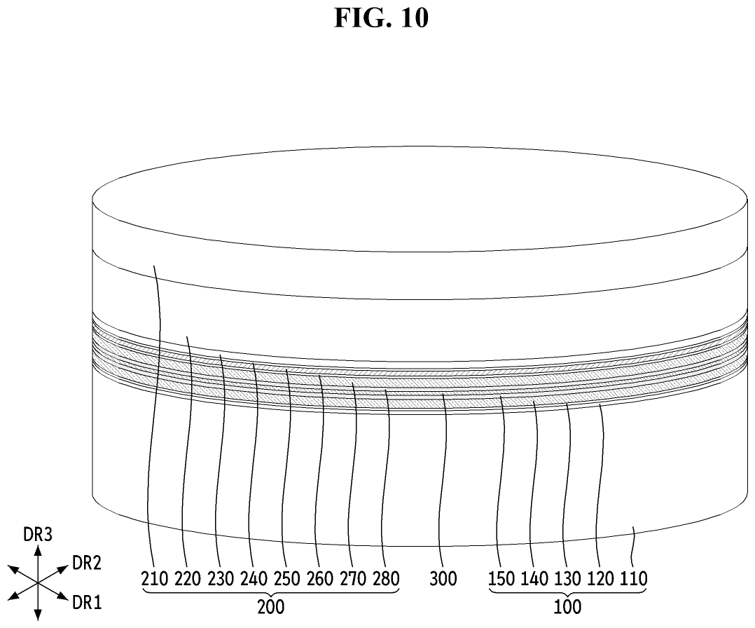

In an embodiment, the third bonding metal layer BMT3 may be formed by the diffusion of bonding metal from the first bonding metal layer BMT1 and the second bonding metal layer BMT2 (or the first and second bonding metal layers 140 and 270 of FIGS. 9 and 10) in the bonding process. The thickness of the third bonding metal layer BMT3 may be less than or equal to the thickness of each of the first bonding metal layer BMT1 and the second bonding metal layer BMT2. For example, the thickness of the third bonding metal layer BMT3 may be smaller than the thickness of each of the first bonding metal layer BMT1 and the second bonding metal layer BMT2.

The first thin film layer DMT1 and the second thin film layer DMT2 may be disposed between the bonding metal layers BMT. The first thin film layer DMT1 and the second thin film layer DMT2 may have materials and/or thicknesses that promote the diffusion of the bonding metal (e.g., titanium (Ti)) included in the first bonding metal layer BMT1 and the second bonding metal layer BMT2 during the bonding process. For example, the first thin film layer DMT1 and the second thin film layer DMT2 may function as diffusion promotion layers (or capping layers), including materials that enhance the diffusion of atoms included in the bonding metal layers BMT during the bonding process for manufacturing the display panel DPN. The thickness of the first thin film layer DMT1 and the second thin film layer DMT2 may be selected to allow the bonding metal from the first bonding metal layer BMT1 and the second bonding metal layer BMT2 to diffuse effectively. The first thin film layer DMT1 and the second thin film layer DMT2 may also be referred to as the “first diffusion promotion layer” and “second diffusion promotion layer,” respectively.

In an embodiment, the first thin film layer DMT1 and the second thin film layer DMT2 may be made of a material that enhances the diffusion coefficient of the bonding material due to a high concentration of grain boundaries and vacancies. For example, the first thin film layer DMT1 and the second thin film layer DMT2 may be made of a bonding metal included in the bonding metal layers BMT, such as a material with an atomic volume similar to the atomic volume of titanium (Ti), or greater than or equal to the atomic volume of titanium (Ti). As an example, each of the first thin film layer DMT1 and the second thin film layer DMT2 may include a material with an atomic volume that is greater than or equal to about 80% of the atomic volume of the bonding metal included in the bonding metal layers BMT. By using materials with an atomic volume that is greater than or equal to about 80% of the atomic volume of the bonding metal, the diffusion of the bonding metal may be effectively promoted.

Table 1 below illustrates the calculated equilibrium atomic volume of several metals, including titanium (Ti). Table 1 shows the calculated equilibrium atomic volume for each metal in Qo, which represents the calculated equilibrium atomic volume in the face-centered cubic (FCC) structure.

TABLE 1

| Metal | FCC Ω₀ |
|---|---|
| Cu | 72 |
| Ag | 108 |
| Au | 113 |
| Ti | 111 |
| Zr | 151 |
| Hf | 140 |
| Ni | 66 |
| Pd | 96 |
| Pt | 100 |

In an embodiment, in the case where the bonding metal layers BMT include titanium (Ti), the first thin film layer DMT1 and the second thin film layer DMT2 may include a material with an atomic volume that is greater than or equal to about 80% of the atomic volume of titanium (Ti). For example, each of the first thin film layer DMT1 and the second thin film layer DMT2 includes at least one of gold (Au), zirconium (Zr), silver (Ag), hafnium (Hf), palladium (Pd), or platinum (Pt).

As the size (e.g., atomic volume) of the material included in the first thin film layer DMT1 and the second thin film layer DMT2 is larger than the size of the bonding metal, it may promote diffusion. For example, the bonding metal layers BMT may be formed with titanium (Ti), while the first thin film layer DMT1 and the second thin film layer DMT2 may be formed with gold (Au), zirconium (Zr), or hafnium (Hf). The diffusion promotion effect may be enhanced, leading to an increase in the diffusion length of the bonding metal. Accordingly, the roughness margin of the bonding metal layers BMT may be greater, and the bonding process may be performed smoothly even at low temperatures.

In an embodiment, in the case where the bonding metal layers BMT include zirconium (Zr), the first thin film layer DMT1 and the second thin film layer DMT2 may be made of a material with an atomic volume that is greater than or equal to about 80% of the atomic volume of zirconium (Zr). For example, each of the first thin film layer DMT1 and the second thin film layer DMT2 may be made of zirconium (Zr) or hafnium (Hf).

In an embodiment, the bonding metal layers BMT, the first thin film layer DMT1, and the second thin film layer DMT2 may all be made of the same material. For example, all of the bonding metal layers BMT, the first thin film layer DMT1, and the second thin film layer DMT2 may be formed of zirconium (Zr). However, the bonding metal layers BMT, the first thin film layer DMT1, and the second thin film layer DMT2 may not be deposited simultaneously but may be deposited or formed sequentially, and thus the bonding metal layers BMT, the first thin film layer DMT1, and the second thin film layer DMT2 may be formed with separate individual films with distinguishable boundaries.

As the diffusion coefficient of the bonding metal increases due to the first thin film layer DMT1 and the second thin film layer DMT2, the diffusion length of the bonding metal may increase. Accordingly, the bonding process may proceed smoothly, enabling the atoms of the bonding metal to diffuse uniformly and/or appropriately without the need for a separate planarization process, such as a chemical mechanical polishing (CMP), to reduce the roughness of the bonding metal layers BMT. For example, by promoting the diffusion of the bonding metal via the first thin film layer DMT1 and the second thin film layer DMT2, the diffusion length of the bonding metal may increase by an amount that exceeds or equals the initial roughness of the bonding metal layers BMT. For example, this process may increase the roughness margin of the bonding metal layers BMT, accommodating the initial roughness condition of the bonding metal layers BMT through the diffusion enhancement provided by the first thin film layer DMT1 and the second thin film layer DMT2. As an example, by promoting diffusion of the bonding metal through the first thin film layer DMT1 and the second thin film layer DMT2, the diffusion length of the bonding metal may increase by an amount greater than or equal to a roughness of approximately about 2 nm to about 4 nm (e.g., approximately 3 nm), corresponding to the initial roughness where the planarization process is not performed after deposition of the bonding metal layers BMT. Accordingly, the bonding process may proceed immediately after deposition of the bonding metal layers BMT without performing a planarization process on the bonding metal layers BMT.

In an embodiment, in order to promote the diffusion of the bonding metal through the first thin film layer DMT1 and the second thin film layer DMT2, the first thin film layer DMT1 and the second thin film layer DMT2 may be formed of thin films having a limited thickness. For example, each of the first thin film layer DMT1 and the second thin film layer DMT2 may have a thickness less than or equal to the diffusion length of the bonding metal included in the first bonding metal layer BMT1 or the second bonding metal layer BMT2.

In an embodiment, each of the first thin film layer DMT1 and the second thin film layer DMT2 may have a thickness in a range of about 1 nm to about 50 nm. As an example, each of the first thin film layer DMT1 and the second thin film layer DMT2 may have a thickness of approximately 10 nm to 20 nm. Accordingly, as the bonding metal may pass through the first thin film layer DMT1 and the second thin film layer DMT2 and move or diffuse to the interface between the first thin film layer DMT1 and the second thin film layer DMT2, a wafer-to-wafer bonding or the like may be performed appropriately.

By promoting diffusion of the bonding metal through the first thin film layer DMT1 and the second thin film layer DMT2, the temperature required for the bonding process may be reduced. For example, as the diffusion length of the bonding metal increases due to the first thin film layer DMT1 and the second thin film layer DMT2, the bonding process (e.g., thermocompression wafer bonding) may be performed at a low temperature of approximately 200° C. or less, without performing a separate planarization process on the bonding metal layers. The promotion of diffusion of the bonding metal through the first thin film layer DMT1 and the second thin film layer DMT2 may shorten the time required for the bonding process. For example, the time required for the bonding process may be shortened, such as shortening the time required for the bonding process from about 2 hours to about 1 hour.

By omitting the planarization process for the bonding metal layers BMT, damage to the reflective layer RMT (e.g., corrosion or peeling of the reflective layer RMT including aluminum (Al) or the like that has weak chemical resistance) caused by chemicals in the planarization process or the like may be prevented. Accordingly, the reliability of the reflective layer RMT and the bonding electrode BDE, which includes the reflective layer RMT, may be improved without requiring a shielding process to protect the reflective layer RMT. As the bonding process temperature decreases, the risk of deterioration of surrounding elements during the bonding process may be minimized.

Accordingly, the manufacturing process of the display device 10, which includes a bonding process or the like for bonding the light emitting elements LE (or an epi-layer including semiconductor layers that form the light emitting elements LE) to the lower substrate 110, may be streamlined or simplified, reducing manufacturing costs. As the reliability of the bonding electrodes BDE improves, the overall reliability of the display device 10 may also be enhanced.

In describing the embodiment of FIGS. 3 and 4, based on the bonding electrode BDE included in the display panel DPN, the streamlining effect of the bonding process has been described in connection with the material and/or the thickness or the like of the bonding metal layers BMT and the thin film layers DMT included in the bonding electrode BDE of the display panel DPN. This effect may occur in the manufacturing process of the display panel DPN. For example, the first bonding metal layer BMT1, the second bonding metal layer BMT2, and the third bonding metal layer BMT3 of FIG. 4 may correspond to the first bonding metal layer 140, the second bonding metal layer 270, and the third bonding metal layer 300 of FIG. 10, respectively. Similarly, the first thin film layer DMT1 and the second thin film layer DMT2 of FIG. 4 may correspond to the first thin film layer 150 and the second thin film layer 280 of FIG. 10, respectively. During the bonding process illustrated in FIG. 10, the diffusion of the bonding metal from the first bonding metal layer BMT1 and the second bonding metal layer BMT2 may be promoted by the first thin film layer DMT1 and the second thin film layer DMT2, enabling the third bonding metal layer BMT3 to form appropriately without performing a planarization process to smooth the first bonding metal layer BMT1 and the second bonding metal layer BMT2.

The bonding layer AMT may be disposed on the connection electrode CNE. The bonding layer AMT may include a conductive material that enhances adhesion between the connection electrode CNE and the bonding electrode BDE. In an embodiment, the bonding layer AMT and the bonding metal layers BMT may include a same material, such as titanium (Ti), but is not limited thereto. For example, the bonding layer AMT may include other metals such as chromium (Cr). The bonding electrode BDE and the connection electrode CNE may be stably bonded or connected by the bonding layer AMT.

The first barrier layer BR1 may be disposed on the bonding layer AMT. The second barrier layer BR2 and the third barrier layer BR3 may be disposed on both surfaces of the reflective layer RMT. For example, the second barrier layer BR2 may be disposed on the bottom surface of the reflective layer RMT, while the third barrier layer BR3 may be disposed on the top surface of the reflective layer RMT.

Each of the first barrier layer BR1, the second barrier layer BR2, and the third barrier layer BR3 may include a material (e.g., a conductive material) suitable for preventing diffusion (e.g., preventing inter-metal diffusion), and may include the same or different materials. Each of the first barrier layer BR1, the second barrier layer BR2, and the third barrier layer BR3 may be formed of a material and/or have a thickness that ensures the conductivity of the bonding electrode BDE. In an embodiment, each of the first barrier layer BR1, the second barrier layer BR2, and the third barrier layer BR3 may include a material with a high inter-metal diffusion prevention effect, such as titanium nitride (TiN), and may be formed as thin films with a limited thickness (e.g., less than or equal to about 20 nm). However, the materials of the first barrier layer BR1, the second barrier layer BR2, and the third barrier layer BR3 are not limited thereto. For example, the first barrier layer BR1, the second barrier layer BR2, and the third barrier layer BR3 may include metals such as nickel (Ni).

The reflective layer RMT may be disposed on the second bonding metal layer BMT2. The bottom surface and top surface of the reflective layer RMT may be covered by the second barrier layer BR2 and the third barrier layer BR3, respectively.

The reflective layer RMT may include a metal with high light reflectivity. As an example, the reflective layer RMT may be made of aluminum (Al). However, the material of the reflective layer RMT is not limited thereto. For example, the reflective layer RMT may also include other metals with high reflectivity, such as molybdenum (Mo), titanium (Ti), copper (Cu), silver (Ag), magnesium (Mg), platinum (Pt), palladium (Pd), gold (Au), nickel (Ni), neodymium (Nd), iridium (Ir), or chromium (Cr).

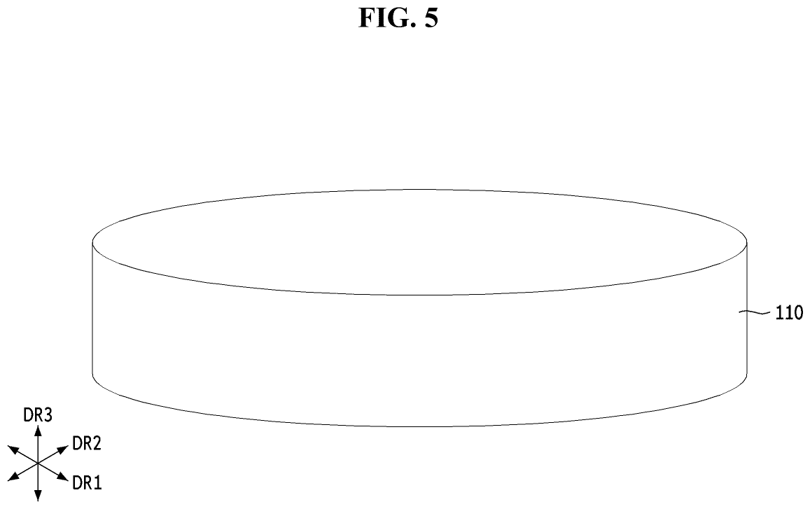

FIGS. 5 to 10 are schematic perspective views showing a method for manufacturing the display device according to an embodiment. For example, FIGS. 5 to 10 illustrate the manufacturing steps for preparing a first substrate 100 and a second substrate 200 for manufacturing the display panel DPN according to an embodiment, as well as bonding the first substrate 100 and the second substrate 200.

In an embodiment, the first substrate 100 and the second substrate 200 of FIGS. 5 to 10 may include multiple cell regions for simultaneously manufacturing multiple display panels DPN. However, the embodiments are not limited thereto. For example, the first substrate 100 and the second substrate 200 may be prepared in a size suitable for manufacturing a single display panel DPN.

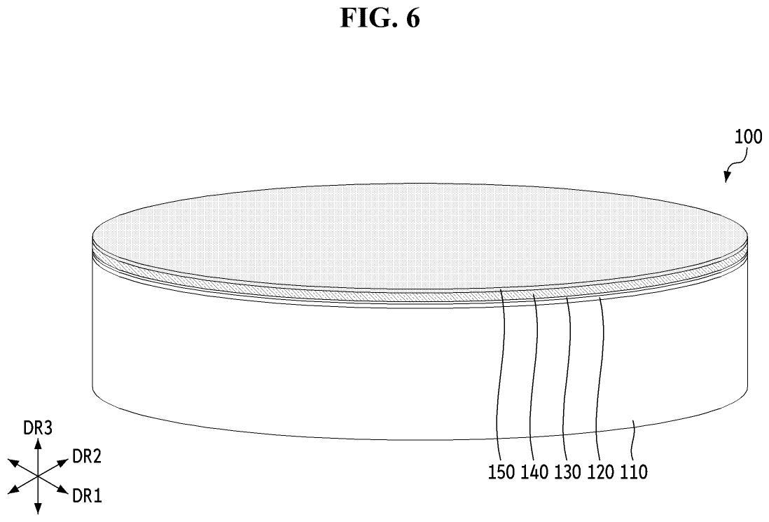

Referring to FIGS. 5 and 6, the first substrate 100, which includes the lower substrate 110 of the display panel DPN, may be prepared. In an embodiment, the lower substrate 110 may include the semiconductor circuit substrate PCL as illustrated in FIG. 3. The lower substrate 110 may further include the connection electrodes CNE and the first insulating layer INS1 on the semiconductor circuit substrate PCL. For example, as illustrated in FIG. 3, the lower substrate 110 may be prepared by forming the semiconductor circuit substrate PCL, which includes the base substrate SB, the pixel circuits PXC, and the pixel electrodes PXE and forming the first insulating layer INS1 and the connection electrode CNE on the semiconductor circuit substrate PCL. The lower substrate 110 may include a cell region for forming at least one display panel DPN. As an example, the lower substrate 110 of FIG. 5 may be prepared in a size and a shape that includes multiple cell regions for simultaneously manufacturing multiple display panels DPN.

Thereafter, as illustrated in FIG. 6, a multilayer lower bonding layer 120, 130, 140, and 150 may be formed on the lower substrate 110. For example, a bonding material layer 120, a first barrier material layer 130, a first bonding metal layer 140 (also referred to as “first bonding material layer”), and a first thin film layer 150 (also referred to as “first thin film material layer”) may be sequentially formed (e.g., deposited) on the lower substrate 110.

The lower bonding layer 120, 130, 140, and 150 may be used to form the bonding electrodes BDE of the pixels PX, and the lower layers of each of the bonding electrodes BDE may be formed from the lower bonding layer 120, 130, 140, and 150. As an example, the bonding layer AMT, the first barrier layer BR1, the first bonding metal layer BMT1, and the first thin film layer DMT1 of FIG. 4 may be formed from the lower bonding layer 120, 130, 140, and 150.

The bonding material layer 120 may be used to form the bonding layer AMT of each of the bonding electrodes BDE, and may be formed using the material or the like previously described as suitable for the material of the bonding layer AMT. The bonding material layer 120 may be patterned into the bonding layer AMT for each of the bonding electrodes BDE through the etching process performed after the bonding process.

The first barrier material layer 130 may be used to form the first barrier layer BR1 of each of the bonding electrodes BDE, and may be formed using the material or the like previously described as the material of the first barrier layer BR1. The first barrier material layer 130 may be patterned into the first barrier layer BR1 of each of the bonding electrodes BDE through the etching process performed after the bonding process.

The first bonding metal layer 140 may be used to form the first bonding metal layer BMT1 of each of the bonding electrodes BDE, and may be formed using the material or the like previously described as the material of the first bonding metal layer BMT1. For example, the first bonding metal layer 140 may be formed of titanium (Ti), or may be formed of zirconium (Zr), nickel (Ni), chromium (Cr) or the like. The first bonding metal layer 140 may have a thickness suitable for a bonding process (e.g., wafer-to-wafer bonding via thermocompression). For example, the first bonding metal layer 140 may have a thickness in a range of about 100 nm to about 300 nm (e.g., about 200 nm), but is not limited thereto. The first bonding metal layer 140 may be patterned into the first bonding metal layer BMT1 of each of the bonding electrodes BDE through the etching process performed after the bonding process.

The first thin film layer 150 may be used to form the first thin film layer DMT1 of each of the bonding electrodes BDE, and may be formed using the material or the like previously described as the material of the first thin film layer DMT1. For example, the first thin film layer 150 may be formed of gold (Au) or zirconium (Zr), or may be formed of silver (Ag), hafnium (Hf), palladium (Pd), platinum (Pt), or the like. The first thin film layer 150 may have a thickness suitable for promoting diffusion of a bonding metal (e.g., titanium (Ti)). For example, the first thin film layer 150 may have a thickness in a range of about 1 nm to about 50 nm (e.g., about 10 nm to about 20 nm), but is not limited thereto. The first thin film layer 150 may be patterned into the first thin film layer DMT1 of each of the bonding electrodes BDE through the etching process performed after the bonding process.

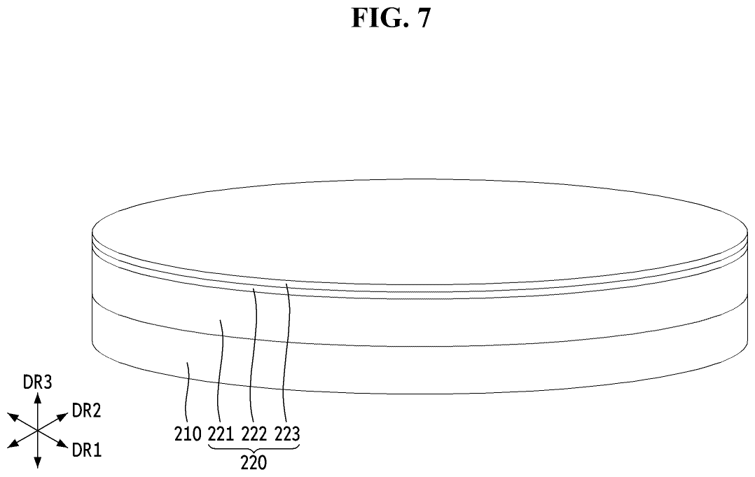

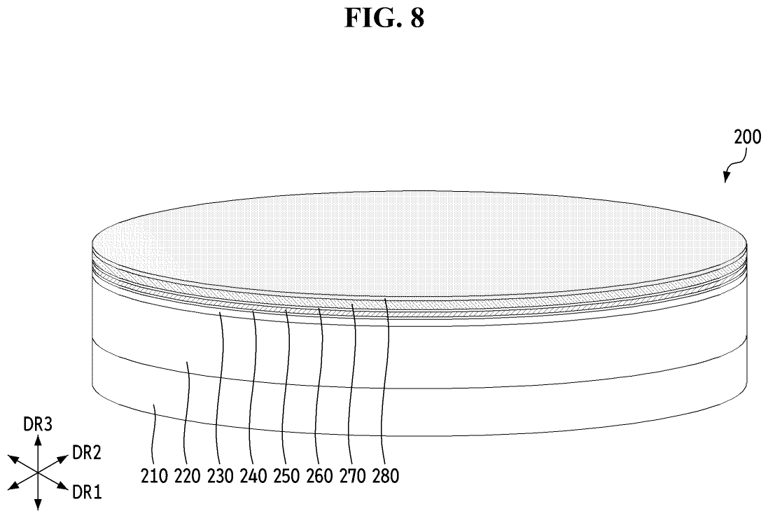

Referring to FIGS. 7 and 8, the second substrate 200, used for forming the light emitting elements LE of the display panel DPN, may be prepared. For example, as illustrated in FIG. 7, an epi-layer 220 may be formed on a semiconductor substrate 210.

The semiconductor substrate 210 may be a manufacturing substrate used for manufacturing the light emitting elements LE. For example, the semiconductor substrate 210 may be a growth substrate suitable for epitaxial growth.

In an embodiment, the semiconductor substrate 210 may include a material such as GaAs, silicon (Si), sapphire, SiC, GaN, or ZnO. As an example, the semiconductor substrate 210 may be a silicon or sapphire substrate. In the case where the epitaxial growth of the epi-layer 220 for manufacturing the light emitting elements LE may be smoothly achieved, the type or material of the semiconductor substrate 210 is not particularly limited.

The epi-layer 220 may be used to form semiconductor layers of each of the light emitting elements LE. For example, the first semiconductor layer SEM1, the light emitting layer EML, and the second semiconductor layer SEM2 of each of the light emitting elements LE illustrated in FIGS. 3 and 4 may be formed from the epi-layer 220. The epi-layer 220 may include a first epi-layer 221 (e.g., an n-type semiconductor layer) for forming the second semiconductor layers SEM2 of the light emitting elements LE, a second epi-layer 222 (e.g., a multiple quantum well layer including a quantum well layer and a barrier layer) for forming the light emitting layers EML of the light emitting elements LE, and a third epi-layer 223 (e.g., a p-type semiconductor layer) for forming the first semiconductor layers SEM1 of the light emitting elements LE. For example, the first epi-layer 221, the second epi-layer 222, and the third epi-layer 223 may be sequentially formed (e.g., deposited) on the semiconductor substrate 210 using the materials previously described as the materials for the second semiconductor layer SEM2, the light emitting layer EML, and the first semiconductor layer SEM1 of the light emitting element LE.

Thereafter, as illustrated in FIG. 8, a multilayer upper bonding layer 230, 240, 250, 260, 270, and 280 may be formed on the epi-layer 220. For example, a first contact material layer 230, a second barrier material layer 240, a reflective material layer 250, a third barrier material layer 260, a second bonding metal layer 270 (also referred to as “second bonding material layer”), and a second thin film layer 280 (also referred to as “second thin film material layer”) may be sequentially formed (e.g., deposited) on the epi-layer 220.

The upper bonding layer 230, 240, 250, 260, 270, and 280 may be used to form the bonding electrodes BDE and the first contact electrodes CTE1 of the pixels PX. For example, the first contact electrodes CTE1 may be formed from the first contact material layer 230. The upper layers of each of the bonding electrodes BDE, for example, the third barrier layer BR3, the reflective layer RMT, the second barrier layer BR2, the second bonding metal layer BMT2, and the second thin film layer DMT2 of FIG. 4 may be formed from the second barrier material layer 240, the reflective material layer 250, the third barrier material layer 260, the second bonding metal layer 270, and the second thin film layer 280 of the second substrate 200, respectively.

The first contact material layer 230 may be used to form the first contact electrodes CTE1 of the pixels PX, and may be formed using the material (e.g., ITO or the like) previously described as the material of the first contact electrodes CTE1. In an embodiment, the first contact material layer 230 may have a thickness suitable for functioning as a contact electrode for smoothly connecting the light emitting elements LE to the respective bonding electrodes BDE. As an example, the first contact material layer 230 may have a thickness of approximately 100 nm, but is not limited thereto. The first contact material layer 230 may be patterned into the first contact electrode CTE1 of each of the pixels PX through the etching process performed after the bonding process.

The second barrier material layer 240 may be used to form the third barrier layer BR3 of each of the bonding electrodes BDE, and may be formed using the material (e.g., TiN, or the like) previously described as the material of the third barrier layer BR3. In an embodiment, the second barrier material layer 240 may be a thin film formed with a limited thickness, for example, a thickness of less than or equal to about 20 nm, but is not limited thereto. The second barrier material layer 240 may be patterned into the third barrier layer BR3 of each of the bonding electrodes BDE through the etching process performed after the bonding process.

The reflective material layer 250 may be used to form the reflective layer RMT of each of the bonding electrodes BDE, and may be formed using the material (e.g., Al or the like) previously described as the material of the reflective layer RMT. In an embodiment, the reflective material layer 250 may have a thickness (e.g., a thickness that ensures a target reflectivity), appropriately reflecting light emitted from the light emitting elements LE. As an example, the reflective material layer 250 may have a thickness in a range of about 100 nm to about 200 nm, but is not limited thereto. The reflective material layer 250 may be patterned into the reflective layer RMT of each of the bonding electrodes BDE through the etching process performed after the bonding process.

The third barrier material layer 260 may be used to form the second barrier layer BR2 of each of the bonding electrodes BDE, and may be formed using the material (e.g., TiN, or the like) previously described as the material of the second barrier layer BR2. In an embodiment, the third barrier material layer 260 may be a thin film formed with a limited thickness, for example, a thickness of less than or equal to about 20 nm, but is not limited thereto. The third barrier material layer 260 may be patterned into the second barrier layer BR2 of each of the bonding electrodes BDE through the etching process performed after the bonding process.

The second bonding metal layer 270 may be used to form the second bonding metal layer BMT2 of each of the bonding electrodes BDE, and may be formed using the material previously described as the material of the second bonding metal layer BMT2. For example, the second bonding metal layer 270 may be formed of titanium (Ti), or may be formed of zirconium (Zr), nickel (Ni), chromium (Cr) or the like. The second bonding metal layer 270 may have a thickness suitable for a bonding process (e.g., wafer-to-wafer bonding via thermocompression). For example, the second bonding metal layer 270 may have a thickness in a range of about 100 nm to about 300 nm (e.g., about 200 nm), but is not limited thereto. The second bonding metal layer 270 may be patterned into the second bonding metal layer BMT2 of each of the bonding electrodes BDE through the etching process performed after the bonding process.

The second thin film layer 280 may be used to form the second thin film layer DMT2 of each of the bonding electrodes BDE, and may be formed using the material previously described as the material of the second thin film layer DMT2. For example, the second thin film layer 280 may be formed of gold (Au) or zirconium (Zr), or may be formed of silver (Ag), hafnium (Hf), palladium (Pd), platinum (Pt), or the like. The second thin film layer 280 may have a thickness suitable for promoting diffusion of a bonding metal (e.g., titanium (Ti)). For example, the second thin film layer 280 may have a thickness in a range of about 1 nm to about 50 nm (e.g., about 10 nm to about 20 nm), but is not limited thereto. The second thin film layer 280 may be patterned into the second thin film layer DMT2 of each of the bonding electrodes BDE through the etching process performed after the bonding process.

Referring to FIGS. 9 and 10, the first substrate 100 and the second substrate 200 may be disposed to face each other, and the bonding process may proceed. For example, after the second substrate 200 is disposed on the first substrate 100 such that the first thin film layer 150 of the first substrate 100 and the second thin film layer 280 of the second substrate 200 face each other, heat and pressure may be applied to bond the first substrate 100 and the second substrate 200. For example, the first substrate 100 and the second substrate 200 may be bonded using a wafer-to-wafer bonding method. In an embodiment, the bonding process may take approximately 1 hour at a process temperature of about 200° C. or lower, but is not limited thereto.

The diffusion of the bonding metal from the first bonding metal layer 140 and the second bonding metal layer 270 may be promoted by the first thin film layer 150 and the second thin film layer 280. For example, the bonding metal from the first bonding metal layer 140 and the second bonding metal layer 270 may diffuse to the interface between the first substrate 100 and the second substrate 200, forming a third bonding metal layer 300 (also referred to as “third bonding material layer”). As an example, the step of bonding the first substrate 100 and the second substrate 200 may include the step of forming the third bonding metal layer 300, which includes a bonding metal (e.g., a bonding metal diffused from the first bonding metal layer 140 and the second bonding metal layer 270), between the first thin film layer 150 and the second thin film layer 280. Accordingly, the first substrate 100 and the second substrate 200 may be appropriately bonded.

The first bonding metal layer 140, the second bonding metal layer 270, and the third bonding metal layer 300 may include the same material. For example, the third bonding metal layer 300 may include the bonding metal included in the first bonding metal layer 140 and the second bonding metal layer 270. The third bonding metal layer 300 may be patterned into the third bonding metal layer BMT3 of each of the bonding electrodes BDE through the etching process performed after the bonding process.

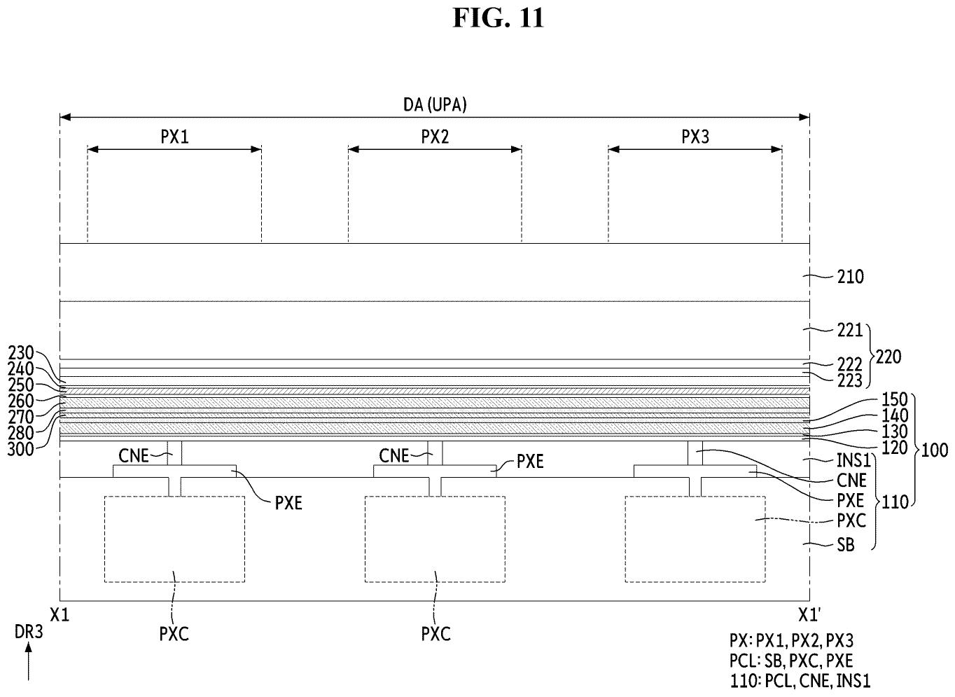

FIGS. 11 to 18 are schematic cross-sectional views illustrating a method for manufacturing the display device according to an embodiment. For example, FIGS. 11 to 18 illustrate a pixel process performed after bonding the first substrate 100 and the second substrate 200. The pixel process may include a process of forming the pixels PX including the light emitting elements LE, in each cell region on the first substrate 100. FIGS. 11 to 18 illustrate only a portion of one cell region, for example, the unit pixel area UPA positioned in one cell region. The unit pixel area UPA of FIGS. 11 to 18 may correspond to the unit pixel area UPA of FIG. 3.

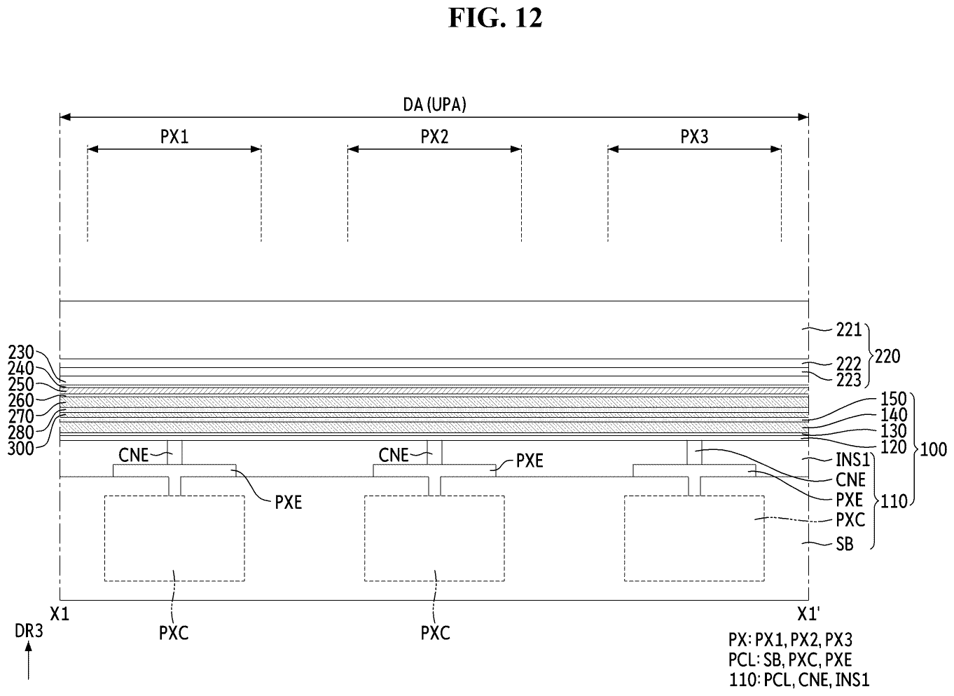

Referring to FIGS. 11 and 12, in addition to FIG. 10, in a state where the second substrate 200 is bonded to the first substrate 100 as illustrated in FIGS. 10 and 11, the semiconductor substrate 210 may be separated from the epi-layer 220. Accordingly, the semiconductor substrate 210 may be removed from the epi-layer 220 as illustrated in FIG. 12.

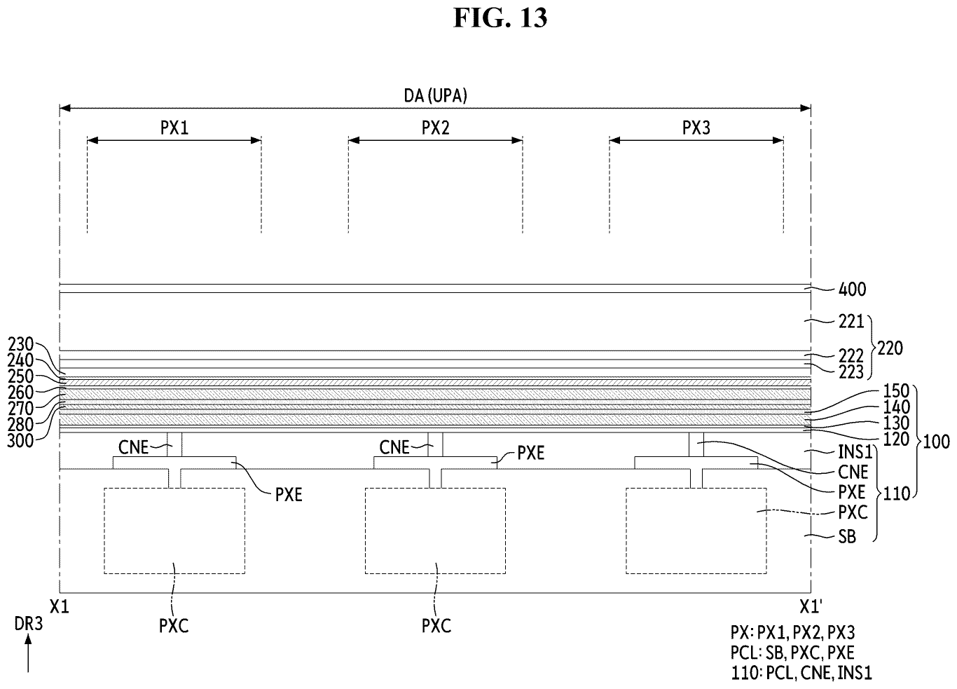

Referring to FIG. 13, a second contact material layer 400 may be formed (e.g., deposited) on the epi-layer 220. The second contact material layer 400 may be used to form the second contact electrodes CTE2 of the pixels PX, and may be formed using the material (e.g., ITO or the like) previously described as the material of the second contact electrodes CTE2. In an embodiment, the second contact material layer 400 may have a thickness suitable for functioning as a contact electrode for smoothly connecting the light emitting elements LE to the common electrode CME. The second contact material layer 400 may allow the transmission of light emitted from the light emitting elements LE. As an example, the second contact material layer 400 may have a thickness of approximately 100 nm, but is not limited thereto. The second contact material layer 400 may be patterned into the second contact electrode CTE2 of each of the pixels PX through the subsequent etching process. In an embodiment, in the case of manufacturing the display panel DPN (e.g., the display panel DPN in which the common electrode CME is directly disposed on the light emitting elements LE) without the second contact electrodes CTE2, the process step for forming the second contact material layer 400 may be omitted.

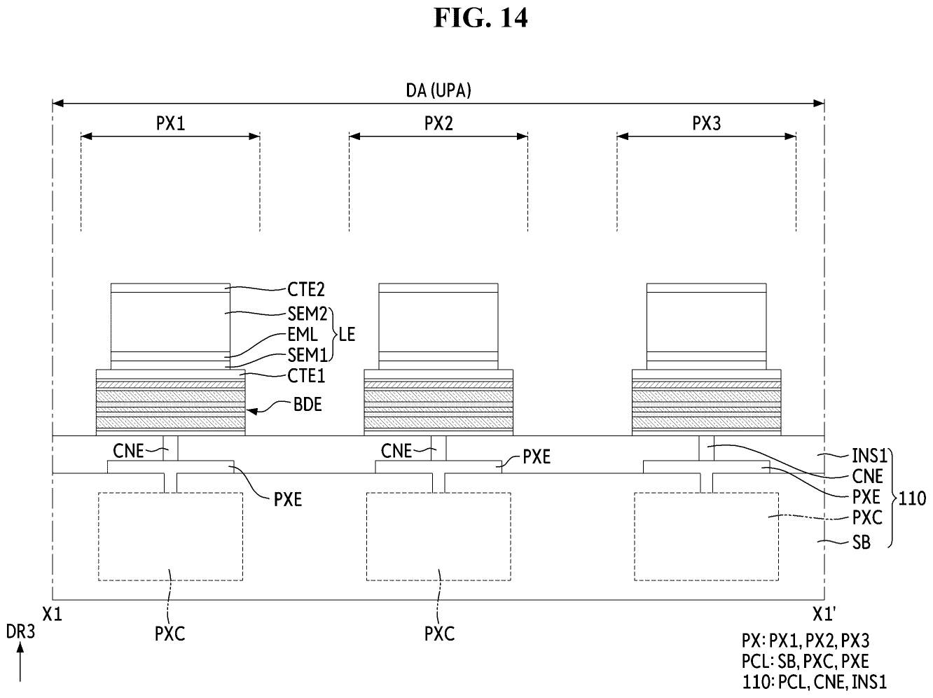

Referring to FIG. 14, in addition to FIG. 13, the bonding electrode BDE, the first contact electrode CTE1, the light emitting element LE, and the second contact electrode CTE2 may be formed in each pixel PX by etching the lower bonding layer 120, 130, 140, and 150, the third bonding metal layer 300, the upper bonding layer 230, 240, 250, 260, 270, and 280, the epi-layer 220, and the second contact material layer 400. In an embodiment, the lower bonding layer 120, 130, 140, and 150, the third bonding metal layer 300, the upper bonding layer 230, 240, 250, 260, 270, and 280, the epi-layer 220, and the second contact material layer 400 may be etched to a desired shape and size using one or more mask processes.

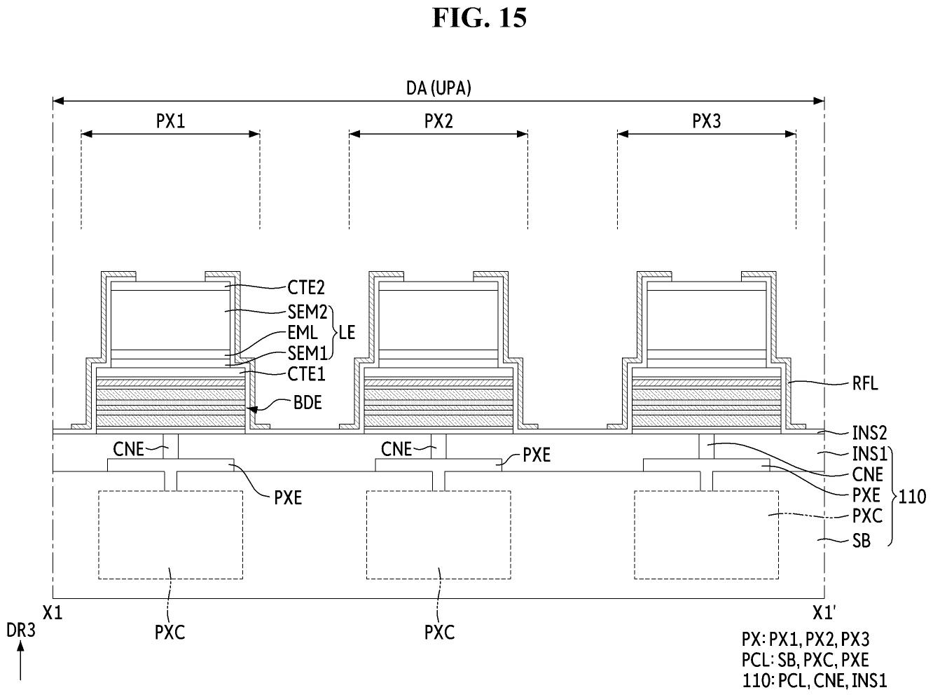

Referring to FIG. 15, the second insulating layer INS2 and the reflection film RFL, which surround the side surfaces of the light emitting elements LE and the like, may be formed. The second insulating layer INS2 and the reflection film RFL may be formed using the materials of the second insulating layer INS2 and the reflection film RFL described above, respectively. The second insulating layer INS2 and the reflection film RFL may be opened at the top of each of the light emitting elements LE. FIG. 15 illustrates an embodiment in which the second insulating layer INS2 and the reflection film RFL are opened prior to the formation of the third insulating layer INS3 and the like, but the embodiments are not limited thereto. For example, after the formation of the third insulating layer INS3, the second insulating layer INS2 and the reflection film RFL, together with the third insulating layer INS3, may be opened at the top of each of the light emitting elements LE.

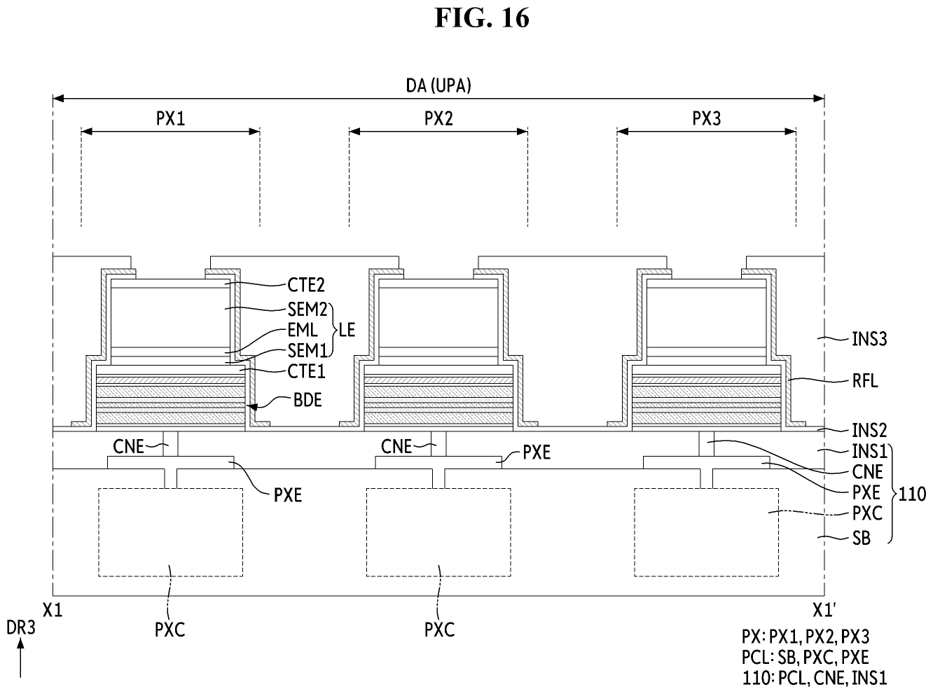

Referring to FIG. 16, the third insulating layer INS3 may be formed on the second insulating layer INS2 and the reflection film RFL. The third insulating layer INS3 may be entirely formed on the lower substrate 110 and the like using the material described above to fill the space between the light emitting elements LE. The third insulating layer INS3 may be opened at the top of each of the light emitting elements LE through an etching process or the like.

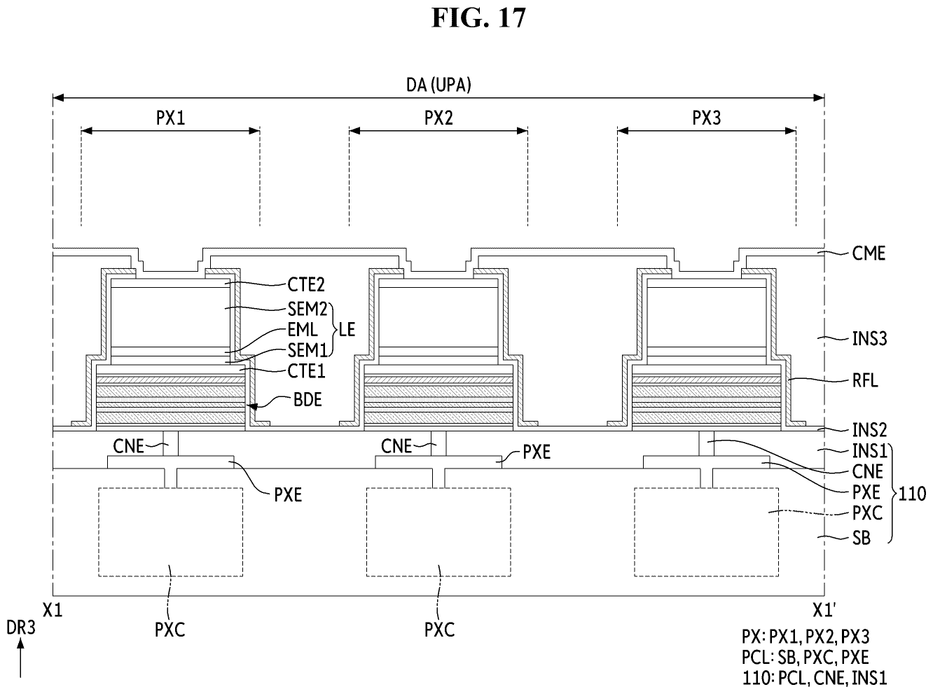

Referring to FIG. 17, the common electrode CME may be formed on the third insulating layer INS3. The common electrode CME may be entirely formed on the light emitting elements LE using the material described above.

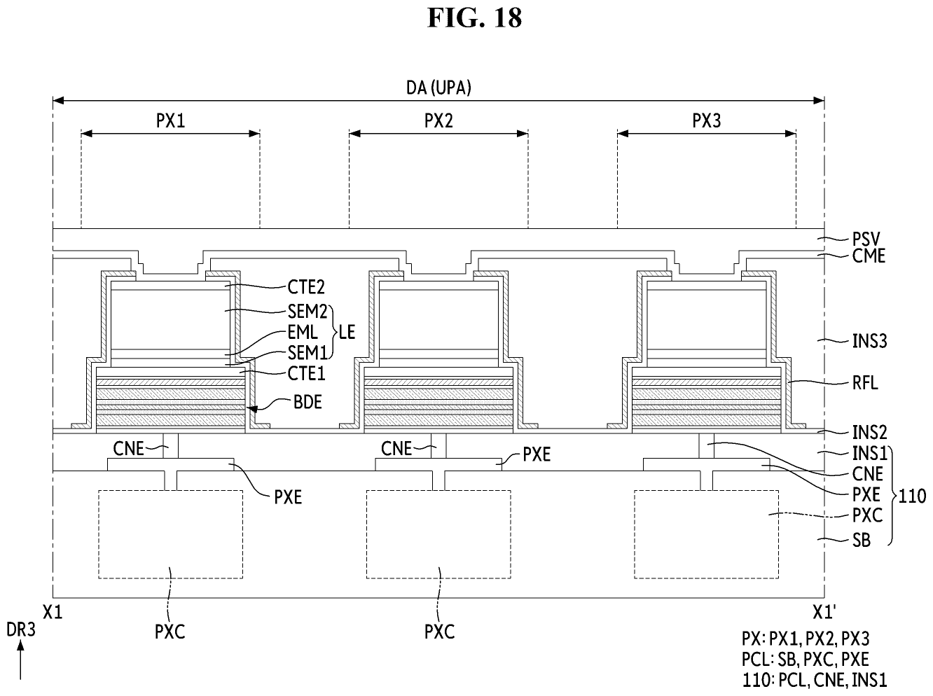

Referring to FIG. 18, the passivation layer PSV may be formed on the common electrode CME. The passivation layer PSV may be entirely formed on the common electrode CME using the material described above.

In an embodiment, in the case where the display panel DPN includes an additional element disposed on the passivation layer PSV, a process for forming or disposing the element may follow. For example, in the case of manufacturing the display panel DPN (or the display device 10) that includes the lens-type optical structure LS as illustrated in FIG. 3, the lens-type optical structure LS may be formed or disposed on the passivation layer PSV. Accordingly, the display panel DPN of FIG. 3 may be completed.

As described above, in the display device 10 and the method of manufacturing the same according to embodiments, the diffusion of the bonding metal may be promoted by forming the first and second thin film layers 150 and 280 on the first and second bonding metal layers 140 and 270 of the first substrate 100, which forms the lower substrate 110 of the display panel DPN, and the second substrate 200, which includes the epi-layer 220 for forming the light emitting elements LE. Accordingly, the first substrate 100 and the second substrate 200 may be smoothly bonded without performing a planarization process to planarize the first and/or second bonding metal layers 140 and 270.

According to embodiments, the manufacturing efficiency of the display device 10 may be improved. For example, the manufacturing process of the display device 10, which is formed from the first substrate 100 and the second substrate 200, may be streamlined or simplified, reducing the manufacturing costs.

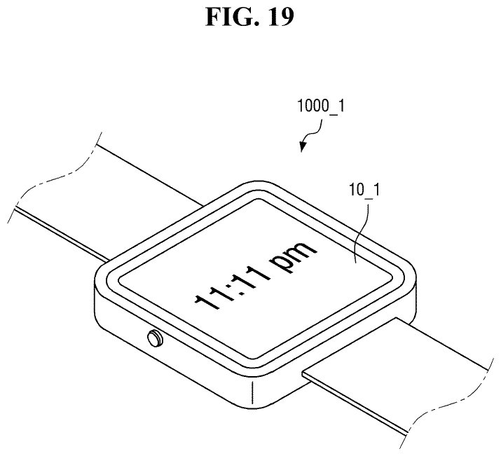

FIG. 19 is a schematic diagram illustrating a smart watch that includes a display device according to an embodiment. Referring to FIG. 19, a display device 10_1 according to an embodiment may be applied to a smart watch 1000_1, which is one example of the smart devices.

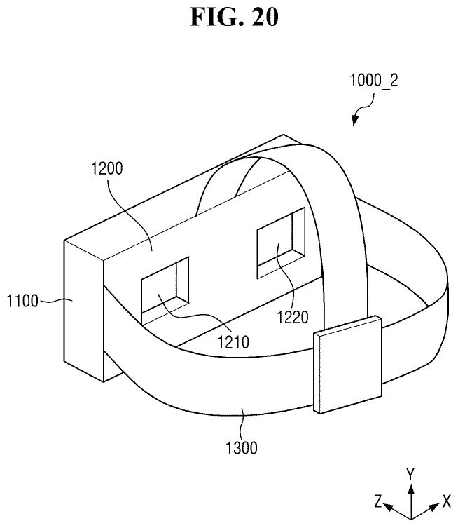

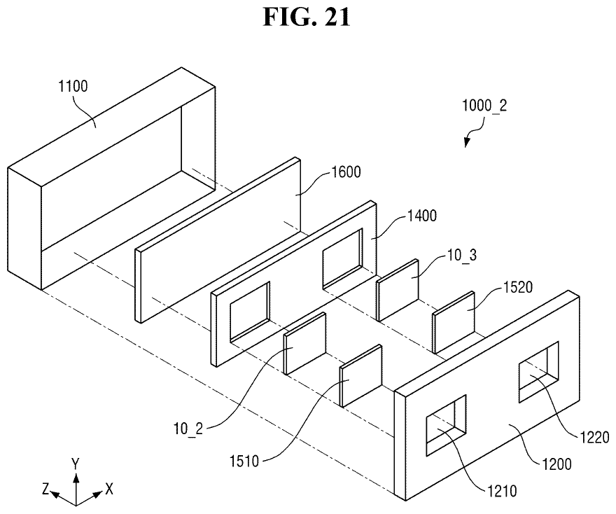

FIGS. 20 and 21 are schematic diagrams illustrating a virtual reality device that includes a display device according to an embodiment.

Referring to FIGS. 20 and 21, a head mounted display 1000_2 according to an embodiment may include a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye. Since each of the first display device 10_2 and the second display device 10_3 is substantially the same as the display device 10 described in conjunction with FIGS. 1 and 2, description of the first display device 10_2 and the second display device 10_3 will be omitted.

The first optical member 1510 may be disposed between the first display device 10_2 and the first eyepiece 1210. The second optical member 1520 may be disposed between the second display device 10_3 and the second eyepiece 1220. Each of the first optical member 1510 and the second optical member 1520 may include at least one convex lens.

The middle frame 1400 may be disposed between the first display device 10_2 and the control circuit board 1600 and between the second display device 10_3 and the control circuit board 1600. The middle frame 1400 may function to support and secure the first display device 10_2, the second display device 10_3, and the control circuit board 1600.

The control circuit board 1600 may be disposed between the middle frame 1400 and the display device housing 1100. The control circuit board 1600 may be connected to the first display device 10_2 and the second display device 10_3 through a connector. The control circuit board 1600 may convert an image source input from an external source into video data DATA, and transmit the video data DATA to the first display device 10_2 and the second display device 10_3 through the connector.

The control circuit board 1600 may transmit the video data DATA corresponding to a left-eye image optimized for the user's left eye to the first display device 10_2, and may transmit the video data DATA corresponding to a right-eye image optimized for the user's right eye to the second display device 10_3. In another embodiment, the control circuit board 1600 may transmit the same video data DATA to both the first display device 10_2 and the second display device 10_3.

The display device housing 1100 may accommodate the first display device 10_2, the second display device 10_3, the middle frame 1400, the first optical member 1510, the second optical member 1520, and the control circuit board 1600. The housing cover 1200 may cover one open surface of the display device housing 1100. The housing cover 1200 may include the first eyepiece 1210, disposed for the user's left eye, and the second eyepiece 1220, disposed for the user's right eye. While FIGS. 20 and 21 illustrate the first eyepiece 1210 and the second eyepiece 1220 as separate components, the disclosure is not limited thereto. The first eyepiece 1210 and the second eyepiece 1220 may also be combined into one.

The first eyepiece 1210 may be aligned with the first display device 10_2 and the first optical member 1510, while the second eyepiece 1220 may be aligned with the second display device 10_3 and the second optical member 1520. Thus, the user may view, through the first eyepiece 1210, the image from the first display device 10_2, magnified as a virtual image by the first optical member 1510, and may view, through the second eyepiece 1220, the image from the second display device 10_3, magnified as a virtual image by the second optical member 1520.

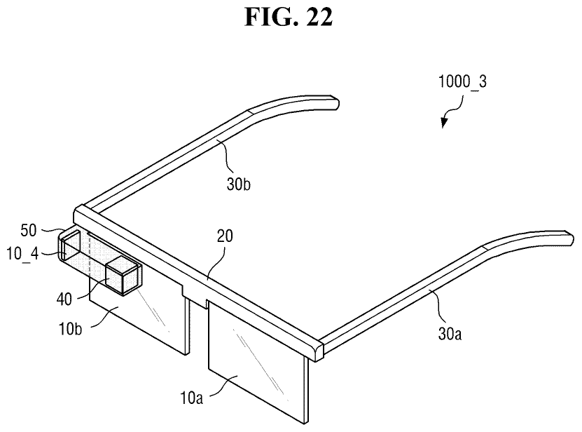

The head mounted band 1300 secures the display device housing 1100 to the user's head, ensuring that the first eyepiece 1210 and the second eyepiece 1220 of the housing cover 1200 remain aligned with the user's left and right eyes, respectively. In the case where the display device housing 1100 is implemented to be lightweight and compact, the head mounted display 1000_2 may be provided with an eyeglass frame, as shown in FIG. 22, instead of the head mounted band 1300.

The head mounted display 1000_2 may further include a battery for power supply, an external memory slot for accommodating an external memory, and an external connection port along with a wireless communication module for receiving image sources. The external connection port may be a universe serial bus (USB) terminal, a display port, or a high-definition multimedia interface (HDMI) terminal. The wireless communication module may be a 5G communication module, a 4G communication module, a Wi-Fi module, or a Bluetooth module.

FIG. 22 is a schematic diagram illustrating a virtual reality device that includes a display device according to another embodiment. FIG. 22 illustrates a virtual reality device 1000_3 to which a display device 10_4 according to an embodiment is applied.

Referring to FIG. 22, the virtual reality device 1000_3 according to an embodiment may be a glasses-type device. The virtual reality device 1000_3 may include the display device 10_4, a left eye lens 10a, a right eye lens 10b, a support frame 20, temples 30a and 30b, a reflection member 40, and a display device housing 50.

FIG. 22 illustrates that the virtual reality device 1000_3 is a glasses-type display device including the temples 30a and 30b. The virtual reality device 1000_3 is not limited to the form shown in FIG. 22, and may be applied in various forms to different electronic devices.

The display device housing 50 may include the display device 10_4 and the reflection member 40. An image displayed on the display device 10_4 may be reflected by the reflection member 40 and provided to the user's right eye through the right eye lens 10b. As a result, the user can view a virtual reality image displayed on the display device 10_4 with the right eye.

Although FIG. 22 illustrates that the display device housing 50 is disposed at the right end of the support frame 20, the disclosure is not limited thereto. For example, the display device housing 50 may be disposed at the left end of the support frame 20, and the image displayed on the display device 10_4 may be reflected by the reflection member 40 and provided to the user's left eye through the left eye lens 10a. As a result, the user can view a virtual reality image displayed on the display device 10_4 with the left eye. In another embodiment, the display device housing 50 may be disposed at both the left end and the right end of the support frame 20, enabling the user to view the virtual reality image displayed on the display device 10_4 through both the left eye and the right eye.

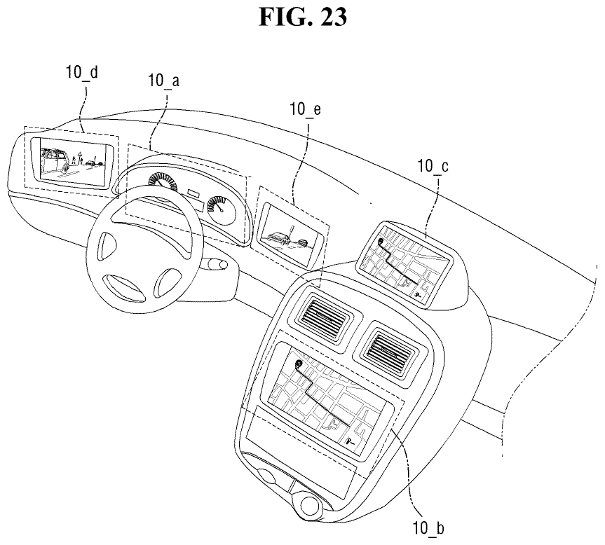

FIG. 23 is a schematic diagram illustrating a dashboard of an automobile and a center fascia, which includes display devices according to an embodiment. FIG. 23 illustrates a vehicle to which the display devices 10_a, 10_b, 10_c, 10_d, and 10_e according to an embodiment are applied.

Referring to FIG. 23, the display devices 10_a, 10_b, and 10_c according to an embodiment may be applied to the dashboard, the center fascia, or the center information display (CID) of the automobile. Further, the display devices 10_d, and 10_e according to an embodiment may be applied to a room mirror display in place of side mirrors of the automobile.

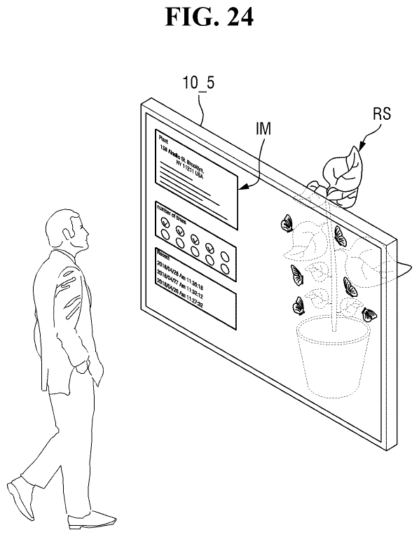

FIG. 24 is a schematic diagram illustrating a transparent display device that includes a display device according to an embodiment.

Referring to FIG. 24, the display device 10_5 according to an embodiment may be applied to a transparent display device. The transparent display device may display an image IM while also transmitting light. Thus, a user located on the front side of the transparent display device can see an object RS or a background on the rear side of the transparent display device, as well as the image IM displayed on the display device 10_5. In the case where the display device 10_5 is applied to a transparent display device, the substrate of the display device 10_5 may include a light transmitting portion capable of transmitting light or may be made of a material capable of transmitting light.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device comprising:
a lower substrate;
a bonding electrode disposed on the lower substrate; and
a light emitting element disposed on the bonding electrode, wherein
the bonding electrode comprises:
a first bonding metal layer and a second bonding metal layer sequentially disposed on the lower substrate, each of the first and second bonding metal layers including a bonding metal;
a third bonding metal layer disposed between the first bonding metal layer and the second bonding metal layer and including the bonding metal;
a first thin film layer disposed between the first bonding metal layer and the third bonding metal layer; and
a second thin film layer disposed between the second bonding metal layer and the third bonding metal layer, and
the first thin film layer and the second thin film layer include a material with an atomic volume that is greater than or equal to about 80% of an atomic volume of the bonding metal.

2. The display device of claim 1, wherein the first bonding metal layer, the second bonding metal layer, and the third bonding metal layer include at least one of titanium (Ti), zirconium (Zr), nickel (Ni), or chromium (Cr).

3. The display device of claim 2, wherein the first thin film layer and the second thin film layer include at least one of gold (Au), zirconium (Zr), silver (Ag), hafnium (Hf), palladium (Pd), or platinum (Pt).

4. The display device of claim 2, wherein
the first bonding metal layer, the second bonding metal layer, and the third bonding metal layer include titanium (Ti), and
the first thin film layer and the second thin film layer include at least one of gold (Au), or zirconium (Zr).

5. The display device of claim 1, wherein each of the first bonding metal layer and the second bonding metal layer has a thickness in a range of about 100 nm to about 300 nm.

6. The display device of claim 5, wherein a thickness of the third bonding metal layer is less than or equal to the thickness of each of the first bonding metal layer and the second bonding metal layer.

7. The display device of claim 1, wherein each of the first thin film layer and the second thin film layer has a thickness in a range of about 1 nm to about 50 nm.

8. The display device of claim 1, wherein the bonding electrode further comprises a bonding layer disposed between the lower substrate and the first bonding metal layer.

9. The display device of claim 1, wherein the bonding electrode further comprises a reflective layer disposed between the second bonding metal layer and the light emitting element.

10. The display device of claim 1, wherein the lower substrate further comprises:
a semiconductor substrate comprising a pixel circuit;
a connection electrode that connects the pixel circuit to the bonding electrode; and
a first insulating layer disposed on the semiconductor substrate and surrounding the connection electrode.

11. The display device of claim 1, wherein the light emitting element comprises a first semiconductor layer, a light emitting layer, and a second semiconductor layer, which are sequentially disposed on the bonding electrode.

12. The display device of claim 11, further comprising:
a second insulating layer surrounding a side surface of the light emitting element;
a common electrode disposed on the light emitting element; and
a reflection film surrounding the side surface of the light emitting element.

13. A method of manufacturing a display device, the method comprising:
preparing a first substrate comprising:
a semiconductor circuit substrate, and
a first bonding metal layer and a first thin film layer sequentially disposed on the semiconductor circuit substrate;
preparing a second substrate comprising:
a semiconductor substrate, and
an epi-layer, a second bonding metal layer, and a second thin film layer sequentially disposed on the semiconductor substrate;
disposing the second substrate on the first substrate such that the first thin film layer and the second thin film layer face each other, and bonding the first substrate to the second substrate;
separating the semiconductor substrate from the epi-layer; and
forming a bonding electrode and a light emitting element by etching:
a lower bonding layer comprising the first bonding metal layer and the first thin film layer,
the epi-layer, and
an upper bonding layer comprising the second bonding metal layer and the second thin film layer, wherein
the first bonding metal layer and the second bonding metal layer include a bonding metal, and
the first thin film layer and the second thin film layer include a material with an atomic volume that is greater than or equal to about 80% of an atomic volume of the bonding metal.

14. The method of claim 13, wherein the first bonding metal layer and the second bonding metal layer include at least one of titanium (Ti), zirconium (Zr), nickel (Ni), or chromium (Cr).

15. The method of claim 14, wherein the first thin film layer and the second thin film layer include gold (Au), zirconium (Zr), silver (Ag), hafnium (Hf), palladium (Pd), or platinum (Pt).

16. The method of claim 14, wherein
the first bonding metal layer and the second bonding metal layer include titanium (Ti), and
the first thin film layer and the second thin film layer include gold (Au), or zirconium (Zr).

17. The method of claim 13, wherein the bonding of the first substrate to the second substrate comprises forming a third bonding metal layer including the bonding metal between the first thin film layer and the second thin film layer.

18. The method of claim 13, wherein each of the first bonding metal layer and the second bonding metal layer has a thickness in a range of about 100 nm to about 300 nm.

19. The method of claim 13, wherein each of the first thin film layer and the second thin film layer has a thickness in a range of about 1 nm to about 50 nm.

20. An electronic device for providing an image, comprising:
a display device comprising a lower substrate, a bonding electrode disposed on the lower substrate, and a light emitting element disposed on the bonding electrode, wherein
the bonding electrode comprises:
a first bonding metal layer and a second bonding metal layer sequentially disposed on the lower substrate, each of the first and second bonding metal layers including a bonding metal;
a third bonding metal layer disposed between the first bonding metal layer and the second bonding metal layer and including the bonding metal;
a first thin film layer disposed between the first bonding metal layer and the third bonding metal layer; and
a second thin film layer disposed between the second bonding metal layer and the third bonding metal layer, and
the first thin film layer and the second thin film layer include a material with an atomic volume that is greater than or equal to about 80% of an atomic volume of the bonding metal.
